(19) United States
(12) Patent Application Publication
(10) Pub. No.: US 2026/0006979 A1
(43) Pub. Date: Jan. 1, 2026

(54) ORGANIC OPTOELECTRONIC DEVICES AND MATERIALS WITH INCREASED EFFICIENCY AND LIFETIME

(71) Applicant: The Regents of the University of Michigan, Ann Arbor, MI (US)

(72) Inventors: Stephen R. Forrest, Ann Arbor, MI (US); Noel Giebink, Ann Arbor, MI (US)

(21) Appl. No.: 19/271,044

(22) Filed: Jul. 16, 2025

Related U.S. Application Data
(62) Division of application No. 19/254,151, filed on Jun. 30, 2025.
(60) Provisional application No. 63/666,461, filed on Jul. 1, 2024.
(60) Provisional application No. 63/717,379, filed on Nov. 7, 2024.

(51) Int. Cl. H10K 39/00; H10K 30/30; H10K 30/57; H10K 39/12

(52) U.S. Cl. CPC H10K 39/621; H10K 30/30; H10K 30/57; H10K 39/12

(57) ABSTRACT

An organic photovoltaic (OPV) device comprises a first arrangement of at least one OPV cell, and a second arrangement of at least one OPV cell, wherein the first and second arrangements are connected in parallel. An organic photovoltaic device comprises a substrate, a first and second electrodes above the substrate, and a heterojunction between the electrodes, comprising a first and second regions, wherein at least a portion of the heterojunction is lightly doped, wherein a conductivity dopant is covalently tied to a host within the first or second regions.

### CROSS-REFERENCE TO RELATED APPLICATIONS

This application is a divisional of U.S. patent application Ser. No. 19/254,151 filed Jun. 30, 2025, which claims priority to U.S. Provisional Patent Application No. 63/666,461 filed Jul. 1, 2024, and to U.S. Provisional Patent Application No. 63/717,379 filed Nov. 7, 2024, each incorporated herein by reference in its entirety.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or sub-cells.

In addition to the pursuit of high device efficiency, OPVs have unique advantages, such as the application of semi-transparent solar cells for use in building integrated photovoltaics (BIPV). Considering the vast surface areas of windows and facades in modern urban environments, developing semi-transparent solar cells with both high efficiency and transmittance has become increasingly important.

The best organic photovoltaic (OPV) cells to date have achieved efficiencies exceeding 20%. (see Z. Zheng, J. Wang, P. Bi, J. Ren, Y. Wang, Y. Yang, X. Liu, S. Zhang and J. Hou, Joule 6 (1), 171-184 (2022)) While OPVs have demonstrated promise for use in semi-transparent power-generating windows, their efficiencies still lag that of other thin film technologies (e.g. CdTe and perovskites), although the efficiency gap has been steadily narrowing. (see S. R. Forrest, Organic Electronics: Foundations to Applications. (Oxford University Press, Oxford, UK, 2020)) In contrast to perovskites, OPVs have shown extraordinary stabilities of decades if not thousands of years. (see Q. Burlingame, X. Huang, X. Liu, C. Jeong, C. Coburn and S. R. Forrest, Nature 573, 394 (2019)) (see Y. Li, X. Huang, K. Ding, H. K. Sheriff, L. Ye, H. Liu, C.-Z. Li, H. Ade and S. R. Forrest, Nature Commun. 12 (1), 1-9 (2021)) OPVs generally use environmentally friendly, low cost, recyclable materials, have very low embodied energy due to low deposition temperatures, and can easily be combined with other solar technologies in multijunction designs. Hence, the possibilities for the use of OPVs as the preferred solar power harvesting technology for windows, rooftop and commodity energy provision is hampered only by their lower power conversion efficiency than competing thin film technologies. Thus there is a need in the art to close the efficiency gap between OPVs and other thin film solar cell technologies by eliminating the source of excess loss in the photogeneration process, which can be done by implementing novel multijunction designs.

Optoelectronic devices rely on the optical and electronic properties of materials to either produce or detect electromagnetic radiation electronically or to generate electricity from ambient electromagnetic radiation. Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors.

Organic photovoltaic cells (OPVs) have sparked considerable interest in recent years owing to their flexibility, light weight, non-toxic nature and semi-transparency that makes them ideal for building integrated and building applied applications. Compared to the commercial solar modules that typically have power conversion efficiencies of PCE=15-22% of sunlight, organics have improved from 10% in 2016 to over 17% in 2019 for single junction devices. Advances have steadily continued, headed toward single junction thermodynamically limited efficiencies of ˜25%, with potentially higher efficiencies based on multijunction cells. This rapid advance has been paced by the development of non-fullerene acceptors (NFAs).

An essential feature of all high-performance photovoltaic devices that exhibit an acceptable level of reproducibility and a long operational lifetime, is that the materials of which they are comprised are of high purity. In crystalline Si photovoltaic cells, the chemical purity of Si has been an important limiting factor in their performance. The introduction of extrinsic impurities can result in significant changes in conductivity by creating lattice strain or by forming interstitial and substitutional defects. As a consequence, the precise control of source material purity is a common strategy for improving the efficiency and reliability of photovoltaics.

In contrast to inorganic photovoltaics, understanding the effects of impurities on organic photovoltaics (OPVs) has received little attention despite their potentially profound impact on performance. In fact, the molecular contaminants left over from synthesis, or that result from decomposition during device operation, can dramatically impact the intrinsic optical and electrical properties of pristine OPV materials (Mateker, W. R. et al. Energy Environ. Sci. 6, 2529-2537 (2013); Salzman, R. F. et al. Org. Electron. 6, 242-246 (2005); Tetreault, et al., Org. Electron. 92, 106091 (2021)). One example is the emergence of photoinduced dimerized products of the fullerene acceptor, C₆₀, during OPV operation, which reduces the exciton lifetime and diffusion length, leading to a significant decrease in device lifetime (Wang, N., et al., Sol. Energy Mater. Sol. Cells 125, 170-175 (2014)). Beyond these changes, impurities can disrupt the crystalline order in molecular solids (Forrest, S. R., et al., J. Appl. Phys. 56, 543-551 (1984)), thereby reducing the charge carrier mobility and cell power conversion efficiency (PCE). Therefore, considerable care must be taken to remove contaminants from the source materials, and to avoid material decomposition during device preparation and operation.

Ternary blend OPVs comprising one donor and two acceptors, or one acceptor and two donors have attracted great interest in recent years (Lu, L., et al., Nat. Photonics 8, 716-722 (2014); Gasparini, N., et al., Nat. Rev. Mater. 4, 229-242 (2019); Yu, R., et al., Adv. Energy Mater. 8, 1702814 (2018); Li, Y. et al. J. Am. Chem. Soc. 141, 18204-18210 (2019); Li, Y. et al. Adv. Mater. 30, 1804416 (2018)). Compared with conventional binary component devices, the introduction of a third molecular species into the bulk heterojunction (BHJ) layer can increase solar spectral coverage, reduce the energy loss, and significantly improve OPV efficiency. In particular, the rapid development of acceptor (A)—donor (D)—acceptor (A) non-fullerene acceptors (NFAs) has led to ternary blend OPVs comprising two NFAs and a polymer donor with PCE approaching 20% under 1 sun intensity, AM 1.5G illumination (Cui, Y. et al. Adv. Mater. 33, 2102420 (2021); Zuo, L. et al. Nat. Nanotechnol. 17, 53-60 (2022); Zhan, L. et al. Adv. Energy Mater. 12, 2201076 (2022); Hultmark, S. et al. Adv. Funct. Mater. 30, 2005462 (2020)).

### SUMMARY OF THE INVENTION

Some embodiments of the invention disclosed herein are set forth below, and any combination of these embodiments (or portions thereof) may be made to define another embodiment.

In one aspect, an organic photovoltaic (OPV) device comprises a first arrangement of at least one OPV cell, and a second arrangement of at least one OPV cell, wherein the first and second arrangements are connected in parallel and/or series.

In some embodiments, the first arrangement includes a first substrate, and the second arrangement includes a second substrate different from the first.

In some embodiments, the OPV device is a 4 terminal (4T) device.

In some embodiments, the first arrangement is transparent to light in a range in which the second arrangement absorbs, and the second arrangement is transparent to light in a range which the first arrangement absorbs.

In some embodiments, the device has an efficiency under AM1.5 illumination selected from the group consisting of: at least 22%, at least 23%, at least 25%, at least 26%, and at least 27%.

In some embodiments, an operating voltage between the first and second arrangements is balanced based on the number of OPV cells in each arrangement.

In some embodiments, a difference between operating voltages of the first and second arrangements is selected from the group consisting of: less than 1 V, less than 0.5 V, less than 0.3 V, less than 0.1V, less than 0.05V and less than 0.01 V.

In some embodiments, when light is applied to the OPV device, the absolute value of the difference in current between the first one or more OPVs and the second one or more OPVs is selected from the group consisting of: less than 1 amp, less than 0.5 amps, less than 0.3 amps, less than 0.1 amps, less than 0.05 amps, and less than 0.01 amps.

In some embodiments, the first arrangement comprises at least two OPV cells connected in series.

In some embodiments, the first arrangement comprises at least two OPV cells connected in parallel.

In some embodiments, the second arrangement comprises at least two OPV cells connected in series.

In some embodiments, the second arrangement comprises at least two OPV cells connected in parallel.

In some embodiments, the first and second arrangements are stacked.

In some embodiments, the first arrangement is above the second arrangement.

In some embodiments, the first arrangement has a transparency selected from the group consisting of: at least 50% transparent, at least 70% transparent, at least 90% transparent, at least 95% transparent, at least 97% transparent and at least 99% transparent.

In some embodiments, the second arrangement has a transparency selected from the group consisting of: at least 50% transparent, at least 70% transparent, at least 90% transparent, at least 95% transparent, at least 97% transparent and at least 99% transparent.

In some embodiments, the first arrangement has a first area and the second arrangement has a second area.

In some embodiments, the second area is selected from the group consisting of: at least 75% of the first area, at least 85% of the first area, at least 95% of the first area, at least 97% of the first area, and at least 99% of the first area.

In some embodiments, the at least one OPV cell in the first arrangement has a narrow bandgap and the at least one OPV cell in the second arrangement has a wide bandgap.

In some embodiments, the at least one OPV cell in the second arrangement has a narrow bandgap and the at least one OPV cell in the first arrangement has a wide bandgap.

In some embodiments, light incident upon the OPV device interacts with the first arrangement and then interacts with the second arrangement.

In some embodiments, the first arrangement absorbs light in a first wavelength range and the second arrangement absorbs light in a second wavelength range. The first and second wavelength ranges can be identical, overlap, or be separate, and can include UV light, visible light, infrared light, and may comprise any range or sub-range within 100-400 nm, 380-780 nm, 700-1000000 nm, and/or 1-1000000 nm.

In some embodiments, the device comprises a flat panel display, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign.

In another aspect, an organic photovoltaic device comprises a substrate, first and second electrodes above the substrate, and a heterojunction between the electrodes, comprising a first and second regions, wherein at least a portion of the heterojunction is lightly doped, wherein a conductivity dopant is covalently tied to a host within the first or second regions.

In some embodiments, the first region comprises a donor region.

In some embodiments, the host molecule comprises a donor host molecule.

In some embodiments, the dopant comprises a p-type dopant.

In some embodiments, the second region comprises an acceptor region.

In some embodiments, the host molecule comprises an acceptor host molecule.

In some embodiments, the dopant comprises a n-type dopant.

In some embodiments, the first or second regions are uniformly doped.

In some embodiments, the open circuit voltage of the device under AM1.5 illumination is selected from the group consisting of: greater than 0.90V, greater than 1.0V, and greater than 1.1V.

In some embodiments, the host comprises a host molecule and/or host polymer.

In some embodiments, the device comprises a flat panel display, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign.

In some embodiments, the donor host molecule comprises PM6, PM7, PTB7-Th, PffBT4T-20D, WF3F, D18, P3HT, PBDB-T, PBDB-T-SF, DR3, ZR1, PTO2, and PTQ10. In some embodiments, the donor host molecule may comprise any other known donor host molecules known in the art.

In some embodiments, the acceptor host molecule comprises IEICO, IEICO-4F, IEICO-4CI, ITIC, ITIC-4F, ITIC-4CI, PYIT, N3, Y1, Y2, Y5, Y6, Y7, Y12, Y16, Coi8DFIC, EH-IDTBR, O-IDTBR, FBR, and BTP-eC9. In some embodiments, the acceptor host molecule may comprise any other known donor host molecules known in the art.

In another aspect, an organic photovoltaic device comprises a substrate; first and second electrodes above the substrate; and a heterojunction between the electrodes, wherein at least one side of the heterojunction is lightly doped.

In one embodiment an acceptor side of the heterojunction is doped with donor and/or a donor side of the heterojunction is doped with acceptor dopants.

In one embodiment, the device further comprises ultrathin self-assembled interface monolayers between the heterojunction and one or more transporting buffer layers.

In another aspect, the present disclosure relates to a compound of Formula (I) or Formula (II):

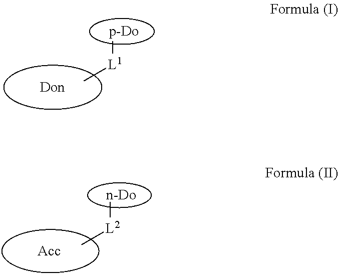

wherein: Don represents a compound capable of functioning as a donor in an organic photovoltaic cell; Acc represents a compound capable of functioning as an acceptor in an organic photovoltaic cell; p-Do represents an organic p-type dopant; n-Do represents an organic n-type dopant; and L¹ and L² independently represent a divalent covalent linking group.

In some embodiments, Don represents a polymeric donor compound.

In some embodiments, L¹ and L² are independently selected from the group consisting of alkylene, cycloalkylene, heteroalkylene, heterocycloalkylene, alkenylene, alkynylene, arylene, heteroarylene, silyl, amine, amide, ester, ether, carbonyl, carbamate, carbonate, sulfamate, sulfonic ester, sulfoximine, sulfonamide, thioether, thioester, disulfide, hydrazine, urea, thiourea, phosphate, phosphonate ester, poly(alkyl ether), heteroatom, and combinations thereof.

In some embodiments, Acc comprises a linear ring system of between three and twenty-five rings D; wherein each ring D is independently a monocyclic ring or a polycyclic fused ring system; and wherein each ring D is a 5-membered to 10-membered carbocyclic or heterocyclic ring; wherein each ring D is fused to an adjacent ring D or bonded to an adjacent ring D via a single bond; and wherein each ring D is optionally substituted with one or more substituents R; each occurrence of R independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and any two adjacent substituents R optionally join to form a fused ring.

In some embodiments, Acc comprises six rings D, seven rings D, or eight rings D.

In some embodiments, each ring D is independently selected from the group consisting of:

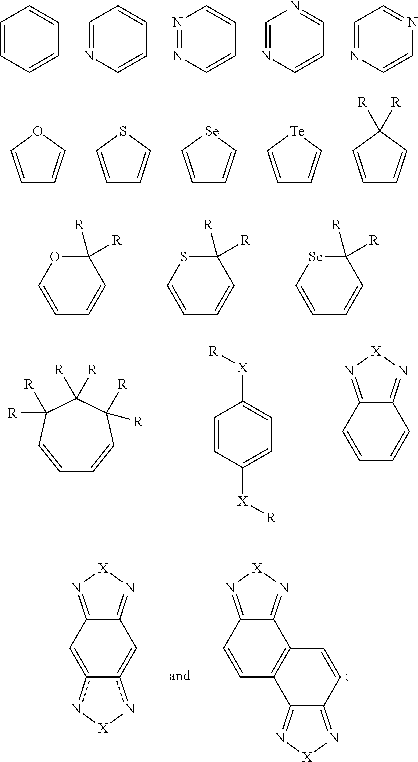

wherein each X is independently selected from the group consisting of oxygen, carbon, hydrogen, sulfur, selenium, and nitrogen; and wherein each ring D is optionally substituted with one or more substituents R.

In some embodiments, Acc comprises one or more groups A; wherein each A is independently selected from the group consisting of:

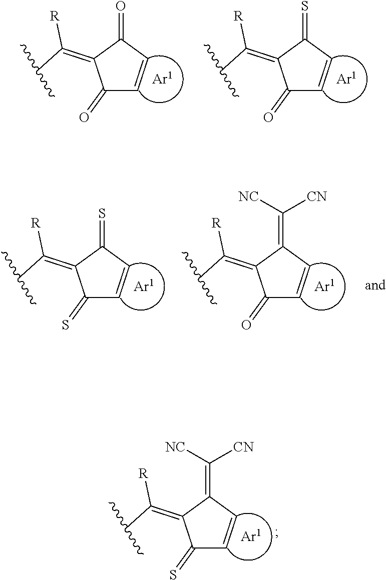

wherein each Ar¹ is independently an aromatic or heteroaromatic ring; each occurrence of R independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and any two adjacent substituents R optionally join to form a fused ring.

In some embodiments, each Ar¹ is independently selected from the group consisting of:

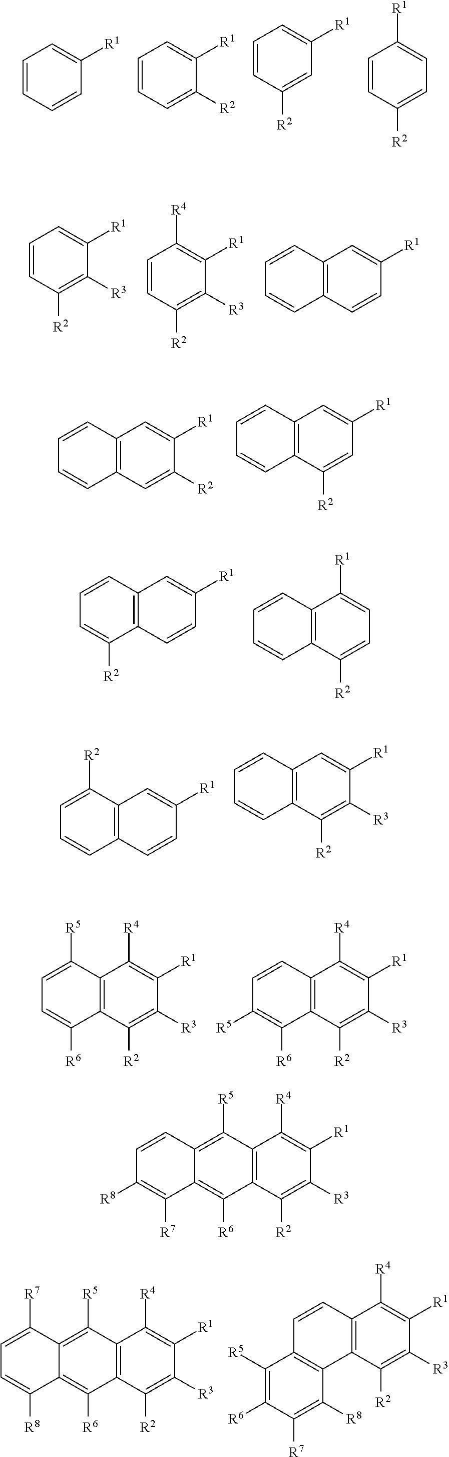

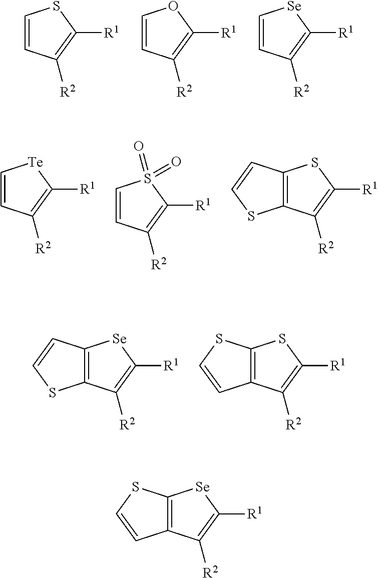

wherein R¹ to R⁸ each independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

In some embodiments, Acc is represented by Formula (A):

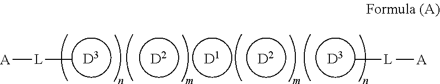

wherein: m is an integer between 0 and 10; n is an integer between 0 and 10; D¹, each D², and each D³ is fused to or covalently bonded to an adjacent ring; D¹, D², and D³ are each independently a monocyclic ring or a polycyclic fused ring system, wherein the monocyclic ring or each ring of the polycyclic fused ring system is a 5-membered to 10-membered carbocyclic or heterocyclic ring; wherein each of D¹, D², and D³ is optionally further substituted with one or more substituents R; L is a divalent linker; each A is independently an acceptor group; each occurrence of R independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents R are optionally joined to form a fused ring.

In some embodiments, D¹ is represented by one of the following structures:

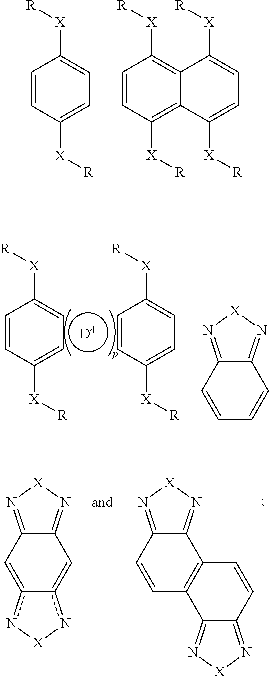

wherein: each X is independently selected from the group consisting of oxygen, carbon, hydrogen, sulfur, selenium, and nitrogen; p is an integer between 0 and 10; wherein D⁴ is a monocyclic ring or a polycyclic fused ring system, wherein the monocyclic ring or each ring of the polycyclic fused ring system is a 5-membered to 10-membered carbocyclic or heterocyclic ring; wherein D⁴ is optionally further substituted with one or more substituents R; and wherein D¹ is optionally substituted with one or more substituents R.

In some embodiments, Acc is represented by Formula (III), Formula (IV), Formula (V), Formula (VI), Formula (VII), or Formula (VIII);

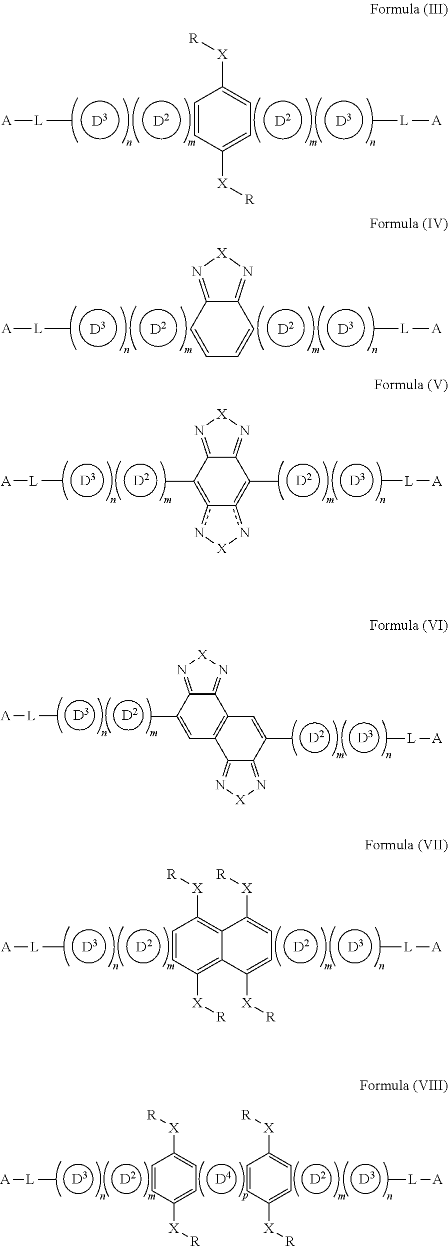

wherein X is selected from the group consisting of oxygen, carbon, hydrogen, sulfur, selenium, and nitrogen.

In some embodiments, n-Do has one of the following structures:

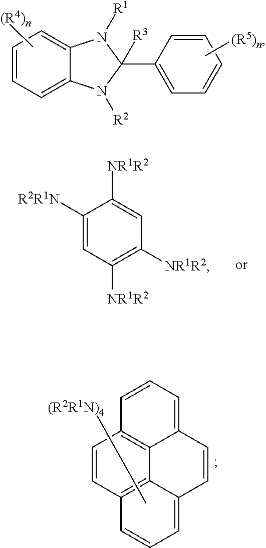

wherein each R¹, R², R³, R⁴, and R⁵ independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents R are optionally joined to form a fused ring; provided that at least one of R¹, R², R³, R⁴, and R⁵ represents the bond to L².

In some embodiments, p-Do has one of the following structures:

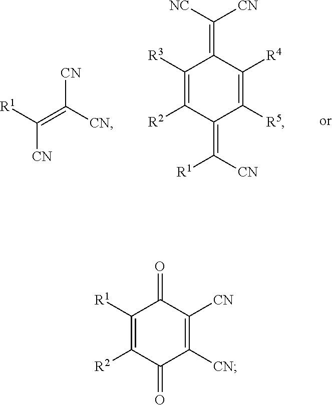

wherein each R¹, R², R³, and R⁴ independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents R are optionally joined to form a fused ring; provided that at least one of R¹, R², R³, and R⁴, represents the bond to L¹.

In some embodiments, Don has one of the following structures:

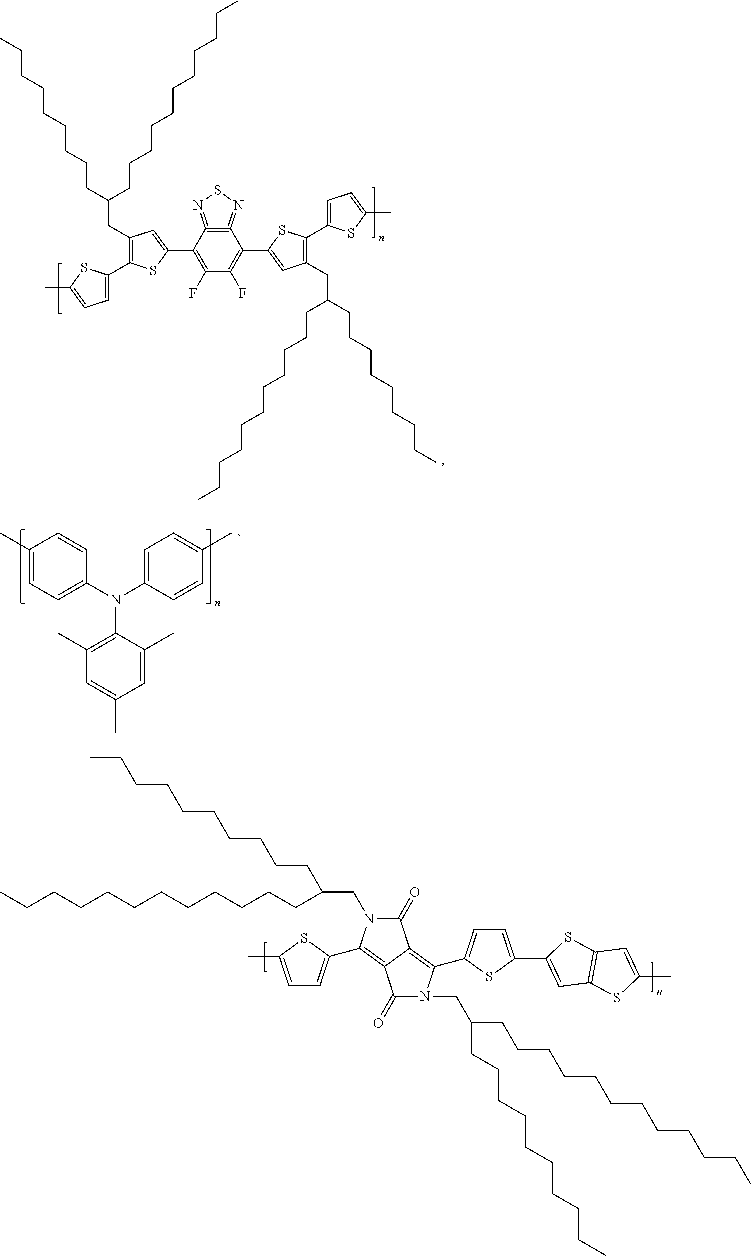

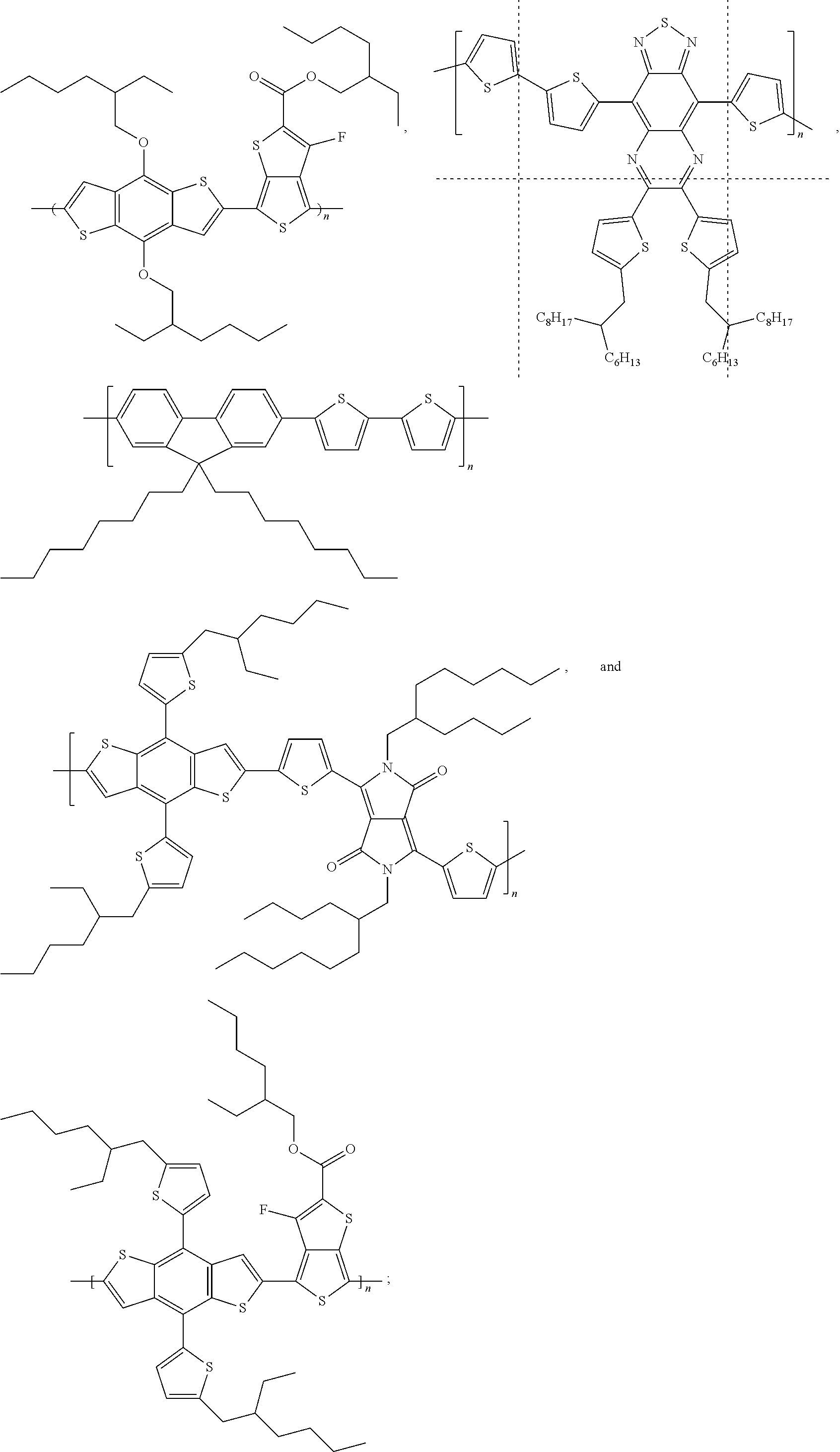

provided that one hydrogen is replaced with the bond to L¹.

In another aspect an organic photovoltaic device comprising at least one compound represented by Formula (I) or Formula (II):

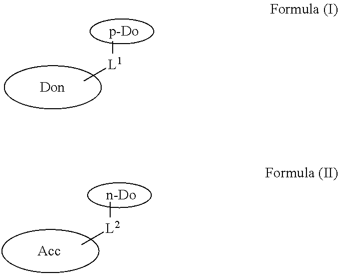

wherein: Don represents a compound capable of functioning as a donor in an organic photovoltaic cell; Acc represents a compound capable of functioning as an acceptor in an organic photovoltaic cell; p-Do represents an organic p-type dopant; n-Do represents an organic n-type dopant; and L¹ and L² independently represent a divalent covalent linking group.

In some embodiments, the organic photovoltaic device comprises an anode, a cathode, and an organic layer disposed therebetween; wherein the organic layer comprises a mixture of the compound of Formula (I) and the compound of Formula (II).

In another aspect, an organic photodetector or a solar cell comprises the organic photovoltaic device as described above.

In another aspect, a consumer product comprises the optoelectronic device as described above.

In another aspect, a formulation comprises the compound as described above.

In another aspect, the present disclosure provides a formulation comprising a compound of Formula (I) or Formula (II) as described herein.

In yet another aspect, the present disclosure provides an optoelectronic device comprising a compound of Formula (I) or Formula (II) as described herein.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a block diagram depicting an exemplary organic light emitting device (OLED) in accordance with some embodiments.

FIG. 2 is a block diagram depicting an exemplary inverted organic light emitting device that does not have a separate electron transport layer in accordance with some embodiments.

FIG. 3 depicts an energy level diagram 900 showing the steps toward photogeneration of free carriers (FC) at an organic HJ. CT=charge transfer state, S=radiative singlet, and T=non-radiative triplet states. Grey arrows are non-radiative processes, blue arrows are absorption, k=rates. A proposed energy level diagram 901 is also shown for a doped type II HJ showing band bending that rapidly separates charge prior to BET at rate, k_{rec}.

FIG. 4 depicts an archetype high reliability NFA-based OPV 903 employing ultrathin (2 nm) C₇₀ anode and monolayer IC-SAM used at the anode and cathode transport layer interfaces, and an alternative self-assembled interface layer materials 904.

FIG. 5 depicts a schematic structure 905 of a 15% efficient organic tandem cell with an optical model of the absorption 906 of an AM1.5G reference spectrum. The dashed red line indicates the charge recombination zone connecting the top and bottom cells. The plots (907, 908) show tandem performance of the cell.

FIG. 6 depicts assembly method 909 of a 4T tandem cell via mechanical stacking. The same process can be used to produce a 2T device by omitting the central contact extension to the edges of the substrates. SC=subcell. (see S. R. Forrest, Organic Electronics: Foundations to Applications. (Oxford University Press, Oxford, UK, 2020)) The plot 910 shows SQ-limited efficiency for 2T and 4T two-junction (2J) tandem cells with a bottom cell energy gap of 1.2 eV vs. top cell energy gap. 4T connection relaxes the bandgap constraint on the top cell since np current density matching is required. A module-level tandem concept 911 is also shown where 4T operation can be achieved while preserving 2T module output by mechanically stacking top and bottom submodules with different cell areas designed to achieve the same current. The bottom-most panel shows a cross-section.

FIG. 7 depicts a process 912 to create stripes of OPV cells series connected in a 1×8 module. Also shown is an SEM image 913 of a separation line between two adjacent cells following peel off, and a perspective view of a module 914.

FIG. 8 is a schematic demonstrating the effect of the present invention on the CT state of the compounds of Formula (I) and Formula (II). OPVs are distinguished from other PVs by their large energy loss. The maximum V_{oc} for OPV cells is set by the charge transfer (CT) state illustrated in bottom left. Lowering its binding energy (E_{b}) with a strong electric field at the donor/acceptor interface (right) provides increases qV_{oc,max} by ΔE_{b}.

FIG. 9 depicts a simulated band diagram for a DA HJ at V_{OC} with (solid) and without (dashed) doping. Doping results in an internal electric field ˜0.8 MV/cm at the heterointerface that decreases the CT binding energy by ΔE_{b}˜0.1 eV.

FIG. 10 depicts an example of n- and p-type dopants (circled) tethered to the D and A molecules, PM6 and Y6, respectively.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems, devices and methods for breaking efficiency and lifetime barriers in organic solar cells. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, 10%, 5%, 1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layers, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “transparent” may refer to a material that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts or electrodes should be minimally absorbing and minimally reflecting of the incident electromagnetic radiation. In some cases, such a contact should be transparent or at least semi-transparent. In one embodiment, the transparent material may form at least part of an electrical contact or electrode.

As used herein, the term “semi-transparent” may refer to a material that permits some, but less than 50% transmission of ambient electromagnetic radiation in relevant wavelengths. Where a transparent or semi-transparent electrode is used, the opposing electrode may be a reflective material so that light which has passed through the cell without being absorbed is reflected back through the cell.

As used and depicted herein, a “layer” refers to a member or component of a device, for example an optoelectronic device, being principally defined by a thickness, for example in relation to other neighboring layers, and extending outward in length and width. It should be understood that the term “layer” is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the length and width may be disturbed or otherwise interrupted by other layer(s) or material(s).

As used herein, a “photoactive region” refers to a region of a device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the term “cathode buffer” is given its ordinary meaning in the art and generally refers to a material which is disposed between a cathode and a photoactive material. Generally, a cathode buffer material aids in reducing the work function of the cathode interface. Those of ordinary skill in the art will be able to select suitable cathode buffer materials with appropriate work functions for use in the methods and devices described herein.

As used herein, the term “anode buffer” is given its ordinary meaning in the art and generally refers to a material which is disposed between a anode and a photoactive material. Generally, a anode buffer material aids in reducing the work function of the anode interface. Those of ordinary skill in the art will be able to select suitable anode buffer materials with appropriate work functions for use in the methods and devices described herein.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

As used herein, the term “band gap” (E_{g}) of a polymer may refer to the energy difference between the HOMO and the LUMO. The band gap is typically reported in electron volts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M⁺+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (ηₚ) may be expressed as:

$${η}_{ρ} = \frac{{V}_{OC} * FF * {J}_{SC}}{{P}_{O}}$$

wherein V_{oc} is the open circuit voltage, FF is the fill factor, J_{SC} is the short circuit current, and P_{O} is the input optical power.

As used herein, “spin coating” may refer to the process of solution depositing a layer or film of one material (i.e., the coating material) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

The terms “halo,” “halogen,” and “halide” are used interchangeably and refer to fluorine, chlorine, bromine, and iodine.

The term “pseudohalogen” refers to polyatomic analogues of halogens, whose chemistry, resembling that of the true halogens, allows them to substitute for halogens in several classes of chemical compounds. Exemplary pseudohalogens include, but are not limited to, nitrile, cyaphide, isocyanide, cyanate, isocyanate, fulminate, thiocyanate, isothiocyanate, selenocyanate, tellurocyanate, azide, tetracarbonylcobaltate, trinitromethanide, and tricyanomethanide groups.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “boryl” refers to a —B(Rₛ)₂ radical or its Lewis adduct —B(Rs)3 radical, wherein Rs can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group is optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group is optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group is optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group is optionally substituted.

The term “alkynyl” refers to and includes both straight and branched chain alkyne radicals. Preferred alkynyl groups are those containing two to fifteen carbon atoms. Additionally, the alkynyl group is optionally substituted.

The terms “aralkyl” or “arylalkyl” are used interchangeably and refer to an alkyl group that is substituted with an aryl group. Additionally, the aralkyl group is optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

In some instances, the preferred general substituents are selected from the group consisting of deuterium, fluorine, alkyl, cycloalkyl, heteroalkyl, alkoxy, aryloxy, amino, silyl, alkenyl, cycloalkenyl, heteroalkenyl, aryl, heteroaryl, nitrile, isonitrile, sulfanyl, and combinations thereof.

In some instances, the preferred general substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the more preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components.

The materials and structures described herein may have applications in devices other than organic solar cells. For example, other optoelectronic devices such as organic electroluminescent devices (OLEDs) and organic photodetectors may employ the materials and structures. More generally, organic devices, such as organic transistors, may employ the materials and structures.

Referring now in detail to the drawings, in which like reference numerals indicate like parts or elements throughout the several views, in various embodiments, presented herein are systems, devices and methods for breaking efficiency and lifetime barriers in organic solar cells.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

As used herein, and as would be understood by one skilled in the art, “HATCN” (referred to interchangeably as HAT-CN) refers to 1,4,5,8,9,11 Hexaazatriphenylenehexacarbonitrile. “TAPC” refers to 4,4′-Cyclohexylidenebis[N,N-bis(4-methylphenyl)aniline]. “B3PYMPM” refers to 4,6-Bis(3,5-di(34yridine-3-yl)phenyl)-2-methylpyrimidine. “BpyTP2” refers to 2,7-Bis(2,2′-bipyridin-5-yl)triphenylene. “LiQ” refers to Lithium Quinolate. “ITO” refers to Indium Tin Oxide. “CBP” refers to 4,4′-Bis(N-carbazolyl)-1,1′-biphenyl. “Ir(ppy)₂acac” refers to bis[2-(2-pyridinyl-N)phenyl-C](acetylacetonato)iridium(III).

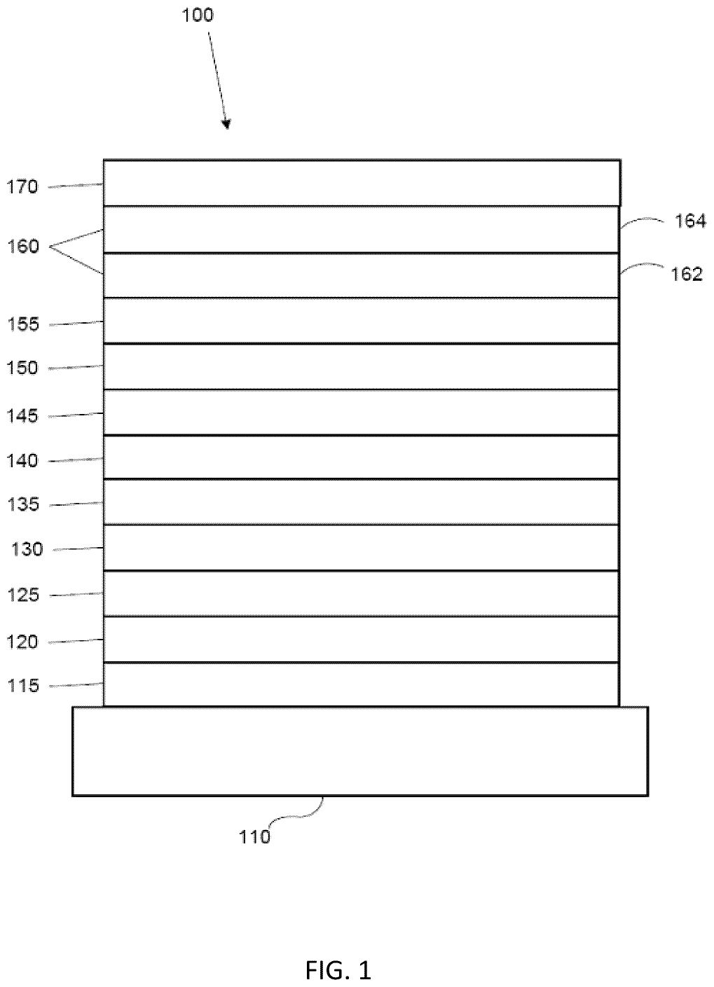

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is Bphen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

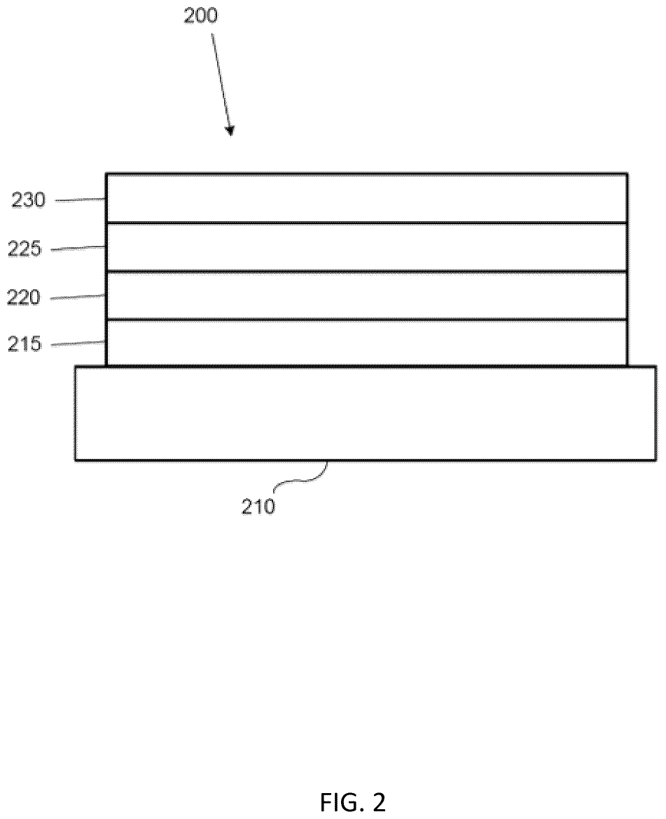

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIG. 1 and FIG. 2 is provided by way of a non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand-held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

The OLED disclosed herein can be incorporated into one or more of a consumer product, an electronic component module, and a lighting panel. The organic layer can be an emissive layer, and the compound can be an emissive dopant in some embodiments, while the compound can be a non-emissive dopant in other embodiments.

In some embodiments, the emissive layer comprises one or more quantum dots.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

In one embodiment, the electronic light display is a white-light organic electroluminescent device (WOLED).

Devices of the present disclosure may comprise one or more electrodes, some of which may be fully or partially transparent or translucent. In some embodiments, one or more electrodes comprise indium tin oxide (ITO) or other transparent conductive materials. In some embodiments, one or more electrodes may comprise flexible transparent and/or conductive polymers.

Layers may include one or more electrodes, organic emissive layers, electron- or hole-blocking layers, electron- or hole-transport layers, buffer layers, or any other suitable layers known in the art. In some embodiments, one or more of the electrode layers may comprise a transparent flexible material. In some embodiments, both electrodes may comprise a flexible material and one electrode may comprise a transparent flexible material.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIG. 1 and FIG. 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In general, the various layers of OLEDs and similar devices described herein may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Some OLED structures and similar devices may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials, structures, and techniques described herein may have applications in devices other than the fabrication of OLEDs. For example, other optoelectronic devices such as organic solar cells and organic photodetectors may employ the materials and structures. More generally, organic devices, such as organic transistors, may employ the materials and structures.

An OLED fabricated using devices and techniques disclosed herein may have one or more characteristics selected from the group consisting of being flexible, being rollable, being foldable, being stretchable, and being curved, and may be transparent or semi-transparent. In some embodiments, the OLED further comprises a layer comprising carbon nanotubes.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

An OLED fabricated according to techniques and devices disclosed herein can be incorporated into one or more of a consumer product, an electronic component module, and a lighting panel. The organic layer can be an emissive layer, and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and/or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

The CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

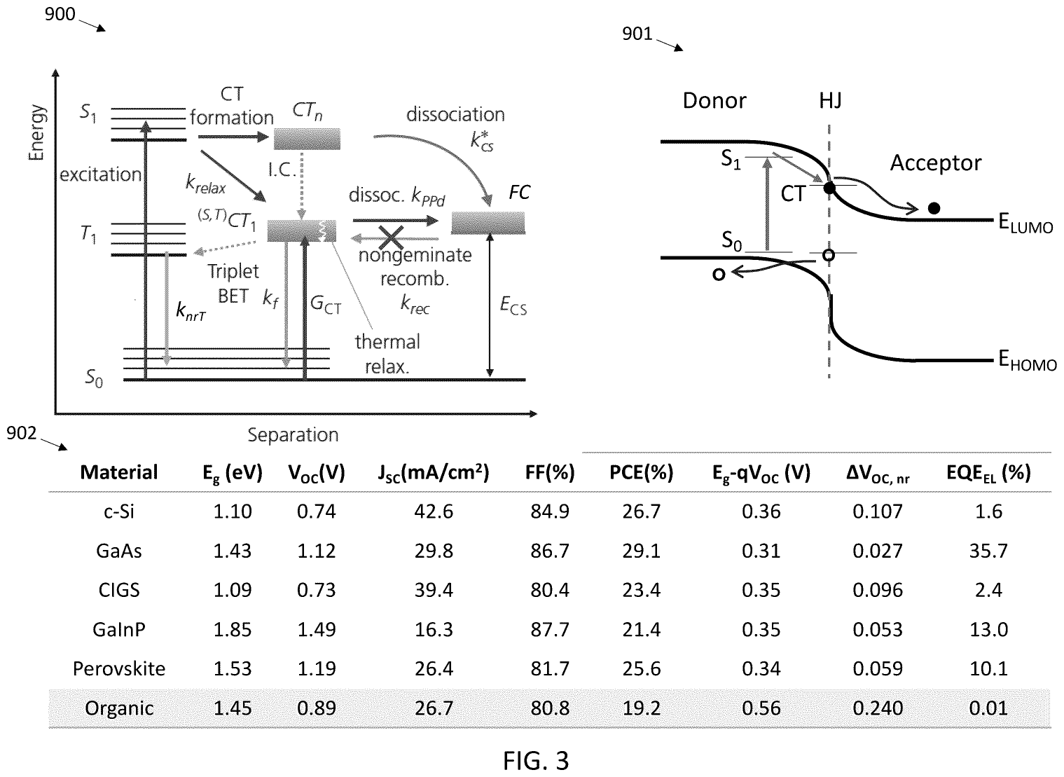

Referring now to FIGS. 3-10, further details of systems, devices, compounds, and methods for breaking efficiency and lifetime barriers in organic solar cells are described.

In some embodiments, an organic photovoltaic (OPV) device 300 comprises a first arrangement 301 of at least one OPV cell, and a second arrangement 302 of at least one OPV cell, wherein the first and second arrangements are connected in parallel. In some embodiments, the first arrangement 301 utilizes a first substrate 303, and the second arrangement 302 utilizes a second substrate 304 different from the first. In some embodiments, the OPV device 300 is a 4 terminal (4T) device or a 2 terminal (2T) device.

In some embodiments, the first arrangement 301 is transparent to light in a range in which the second arrangement 302 absorbs, and/or the second arrangement 302 is transparent to light in a range which the first arrangement 301 absorbs. In some embodiments, the device 300 has an efficiency under AM1.5 illumination selected from the group consisting of: at least 22%, at least 23%, at least 25%, at least 26%, and at least 27%.

In some embodiments, an operating voltage and/or current between the first and second arrangements (301, 302) is balanced based on the number of OPV cells in each arrangement. In some embodiments, a difference between operating voltages of the first and second arrangements (301, 302) is less than 1 V, less than 0.5 V, less than 0.3 V, less than 0.1V, less than 0.05V, and/or less than 0.01 V.

In some embodiments, when light is applied to the OPV device, the absolute value of the difference in current between the first one or more OPVs and the second one or more OPVs is less than 1 amp, less than 0.5 amps, less than 0.3 amps, less than 0.1 amps, less than 0.05 amps, and/or less than 0.01 amps.

In some embodiments, the first arrangement 301 comprises at least two OPV cells connected in series. In some embodiments, the first arrangement 301 comprises at least two OPV cells connected in parallel. In some embodiments, the second arrangement 302 comprises at least two OPV cells connected in series. In some embodiments, the second arrangement 302 comprises at least two OPV cells connected in parallel. In some embodiments, the first and second arrangements (301, 302) are stacked. In some embodiments, when an OPV cell is connected in series or parallel with another OPV cell, they are connected by a shared common electrode. In other words, a single electrode is connected to the first OPV cell and to the second OPV cell.

In another aspect, an organic photovoltaic device comprises a substrate, first and second electrodes above the substrate, and a heterojunction between the electrodes, comprising a first and second regions, wherein at least a portion of the heterojunction is lightly doped, wherein a conductivity dopant is covalently tied to a host within the first or second regions.

In some embodiments, the first region comprises a donor region. In some embodiments, the host molecule comprises a donor host molecule. In some embodiments, the dopant comprises a p-type dopant.

In some embodiments, the second region comprises an acceptor region. In some embodiments, the host molecule comprises an acceptor host molecule. In some embodiments, the dopant comprises a p-type dopant.

In some embodiments, the first or second regions are uniformly doped. In some embodiments, the donor host molecule comprises PM6, PM7, PTB7-Th, PffBT4T-20D, WF3F, D18, P3HT, PBDB-T, PBDB-T-SF, DR3, ZR1, PTO2, and PTQ10. In some embodiments, the donor host molecule may comprise any other known donor host molecules known in the art. In some embodiments, the acceptor host molecule comprises IEICO, IEICO-4F, IEICO-4CI, ITIC, ITIC-4F, ITIC-4CI, PYIT, N3, Y1, Y2, Y5, Y6, Y7, Y12, Y16, Coi8DFIC, EH-IDTBR, O-IDTBR, FBR, and BTP-eC9. In some embodiments, the acceptor host molecule may comprise any other known donor host molecules known in the art.

In some embodiments, new materials and device design strategies are used for demonstrating both two and four terminal (2T and 4T) multijunction cells. In some embodiments, these materials and designs ensure long laboratory and outdoor operational lifetimes when deployed in 50-100 cm² mini-modules. In some embodiments, a power conversion efficiency (PCE) greater than 27% and projected operational lifetimes greater than 20 years is achieved. Thin film OPVs can leverage the existing current infrastructure and workforce for manufacturing organic LEDs (OLEDs) to serve a $60B display industry that produces 1.5-2 million displays per day. OPVs, too, can be produced by extremely high volume and rapid roll-to-roll (R2R) deposition on flexible substrates. (see M. Hölsel, D. Angmo, R. R. Søndergaard, G. A. dos Reis Benatto, J. E. Carlé, M. Jorgensen and F. C. Krebs, Advanced Science 1 (1), 1400002 (2014)) (see B. Qu and S. R. Forrest, Appl. Phys. Lett. 113, 053302 (2018)) Success of these materials and designs can catapult OPVs into becoming the leading source of reliable, environmentally friendly and very high efficiency, low cost, thin film solar cell technology.

To achieve a record efficiency of 27%, the three objectives were explored: 1.) Decreasing energy losses via doping; 2.) Demonstrating novel multijunction device designs and fabrication; 3.) Proving reliable minimodules via indoor and outdoor testing.

The table 902 in FIG. 3 compares typical performance characteristics of several solar cell technologies. The high nonradiative open circuit voltage loss, DV_{OC,nr}, and the correspondingly low external quantum efficiency of electroluminescence when the cell is driven in forward bias (EQE_{EL}) stand out against prior technologies, while the short circuit current densities, J_{SC}, and fill factors (FF) are comparable. The reason for the high DV_{OC,nr} and low EQE_{EL} is illustrated in the energetics of charge generation in the top left plot. The primary optical excitation in the donor (D) or acceptor (A) materials forming the heterojunction (HJ) is to the singlet (Si) excited molecular state. This converts to the charge transfer (CT) state that is shared between A and D molecules. The more loosely bound CT state then dissociates to produce free carriers (FC) that are collected at the electrodes. Losses are incurred due to back electron transfer (BET) to the non-radiative triplet (T₁) in the D and/or A material from the CT or FC states. T₁ is at lower energy than S₁, leading to non-radiative recombination once the excitation is trapped in T₁. Since the OPV D and A materials are undoped, there is no local electric field at the HJ to separate the FC pair, resulting in efficient BET.

In one embodiment, one goal was to significantly reduce BET of free electrons and holes by lightly doping the HJ with donor dopants on the A side of the junction (making it slightly n-type), and acceptor dopants on the D side, resulting in a depletion region that separates the photogenerated charges (see FIG. 3, 901). In organics, a dopant is a molecule which has frontier orbitals (i.e. the valence-like highest occupied molecular orbital, HOMO, or conduction-like lowest unoccupied MO, LUMO) only slightly offset from the opposite energy level in the “host” organic semiconductor. For example, a donor dopant has its HOMO nearly resonant with the LUMO of the host, thus transferring an excess electron to the host. There are two challenges to this scheme: 1.) The dopants should be segregated on opposite sides of the HJ so as to avoid compensation; 2.) the dopant energies must lie close to their respective host HOMO or LUMO levels to avoid quenching the excited states. In some embodiments, only one side of the junction needs to be doped to produce the built-in electric field needed to separate charges at the heterojunction.

In some embodiments, a set of donor and acceptor dopants are used to segregate to the D and A regions. In some embodiments, the dopants' energy levels are within 50 meV of the LUMO and HOMO of the D and A hosts. Conductivity doping of organics is widely used in OLEDs, but has not been applied to OPV active regions due to the potential for exciton quenching. In the disclosed approach, minimal quenching is expected since the exciton lifetime in OPVs is on the order of ps due to fast exciton dissociation at the D/A HJ. In one example, previously reported p-type and n-type dopants in the A and D materials were identified, respectively, and match with the best reported OPV materials (e.g. Y6 as A, and PM6 as D) to achieve the desired small HOMO/LUMO offset between the D or A hosts and the dopants. (see A. D. Scaccabarozzi, A. Basu, F. Aniés, J. Liu, O. Zapata-Arteaga, R. Warren, Y. Firdaus, M. I. Nugraha, Y. Lin and M. Campoy-Quiles, Chem.Rev. 122-, 4420 (2021)) For example, F₄TCNQ has an electron affinity of −5.3 eV, close to the HOMO of many donors, while decamethylcobaltocene has an ionization potential of −3.3 eV, close to the LUMO of numerous non-fullerene acceptors (NFAs). Initial studies focused on planar bilayer OPVs, allowing observation of the effect of doping level and dopant/host energetics on cell performance in the absence of dopant diffusion into the opposite layer material during fabrication. In one embodiment the selective miscibility of the dopants in a D or A host is used to segregate dopants in the D/A blended bulk HJ (BHJ). If dopant diffusion into the unintended phase occurs, the dopants can be anchored to the D or A species, thereby preventing interdiffusion while facilitating BHJ fabrication.

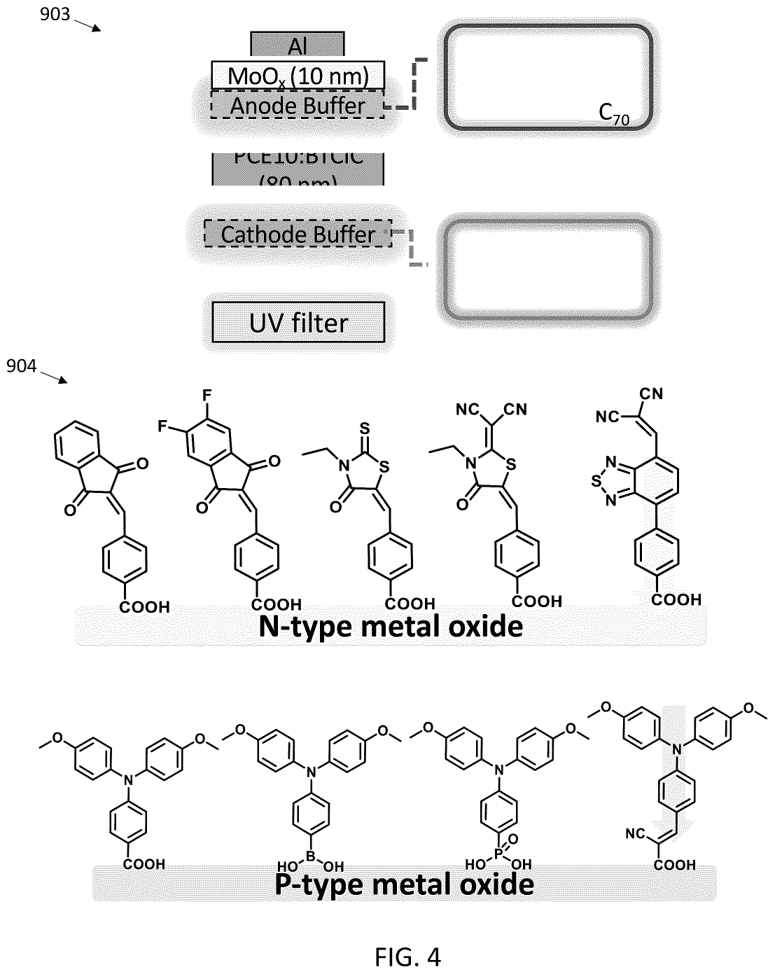

A distinct advantage of OPVs is the ability to stack multiple subcells without restrictions of lattice matching between materials, allowing for a broad spectral coverage and large V_{OC}. In some examples, both 2T and 4T configurations were explored for tandem and higher order stacked cells. While 2T devices are inherently simple, they require current density matching between subcells. 4T cells eliminate this restriction, but complicate cell interconnection and power management at the module level. The basic subcell architecture 903 in FIG. 4 includes a back surface UV filter to prevent damage to the organics. Past studies have shown that 600 nm of spin-cast ZnO on the substrate is effective and inexpensive for this purpose. Recognizing that this UV light need not be wasted, in some examples a ZnO protective layer is doped with inexpensive inorganic phosphors to downconvert the UV light to longer wavelengths absorbed in the sub-cells to tune current matching (up to 2 mA/cm² difference can be accommodated) in the 2T device. The cell includes metal oxide cathode and anode buffer layers (typically MoO₃ and ZnO, respectively). In prior work thiophene-based NFAs used in high efficiency cells tend to react with the buffer layers. (see Y. Li, X. Huang, K. Ding, H. K. Sheriff, L. Ye, H. Liu, C.-Z. Li, H. Ade and S. R. Forrest, Nature Commun. 12 (1), 1-9 (2021)) To eliminate these reactions, ultrathin, self-assembled interface monolayers are inserted between the BHJ and the transporting buffer layers. IC-SAM and C₇₀ serve this function at the BHJ/ZnO and MoO₃ interfaces, respectively, leading to cell extrapolated lifetimes of greater than 30 years. (see Y. Li, X. Huang, K. Ding, H. K. Sheriff, L. Ye, H. Liu, C.-Z. Li, H. Ade and S. R. Forrest, Nature Commun. 12 (1), 1-9 (2021)) However, these same materials may not result in long-term reliability of very high efficiency cells. Hence, in some examples, new interface protection layers (see FIG. 4, 903) are employed. For n-type metal-oxide buffers, materials functionalized using electron-withdrawing groups are employed, while triarylamine groups are tied to hydroxyl anchors to the p-metal-oxide.

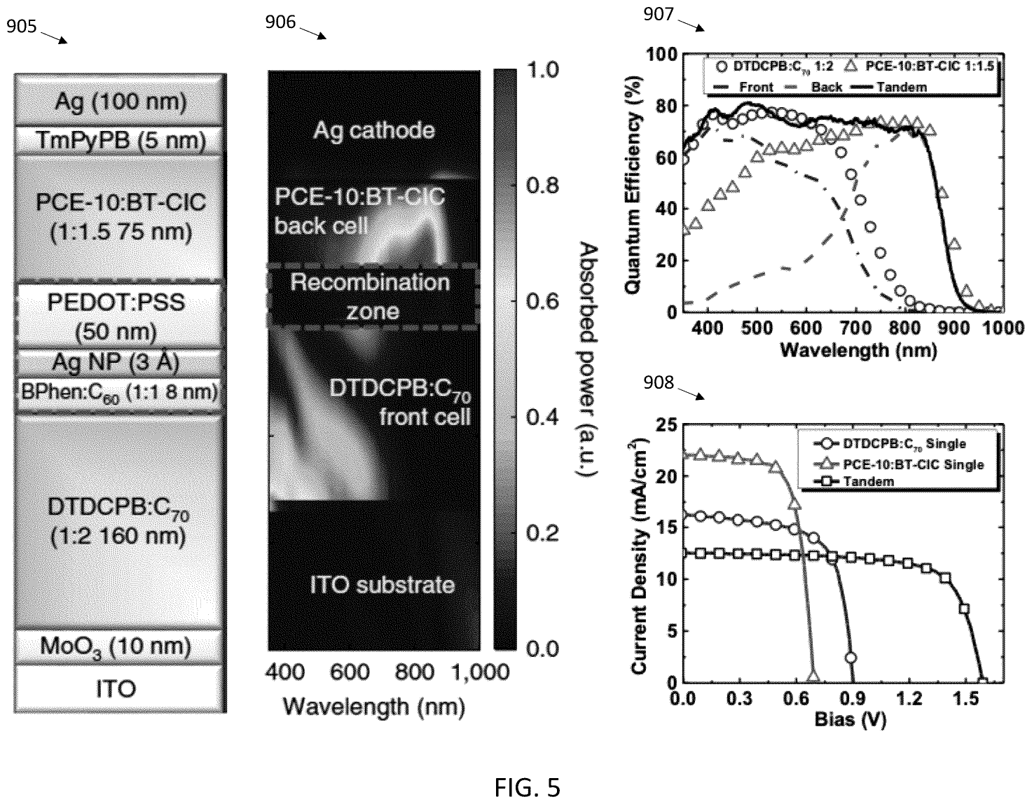

An exemplary 2T design, shown in FIG. 5 is a starting point for exemplary multijunction devices. In some embodiments, the back cell is a polymer:NFA blend (PCE-10 and BT-CIC, respectively), while the front cell is a vapor-deposited small molecule cell. This design achieved PCE=15%. (see X. Che, Y. Li, Y. Qu and S. R. Forrest, Nature Energy 3, 422 (2018)) Replacing the top binary with a ternary blend of one donor and 2 acceptors resulted in 15.9% efficiency. (see X. Huang, B. Sun, Y. Li, C. Jiang, D. Fan, J. Fan and S. R. Forrest, Applied Physics Letters 116 (15) (2020)) One goal was to combine very high efficiency materials developed either internally or that are commercially available, such as PM6:Y6. In one example, multijunction cells (see FIG. 5) were optically modeled, accounting for luminescent emission from the phosphor-doped ZnO UV protective layer, to determine layer thicknesses and positions for achieving PCE=27%.

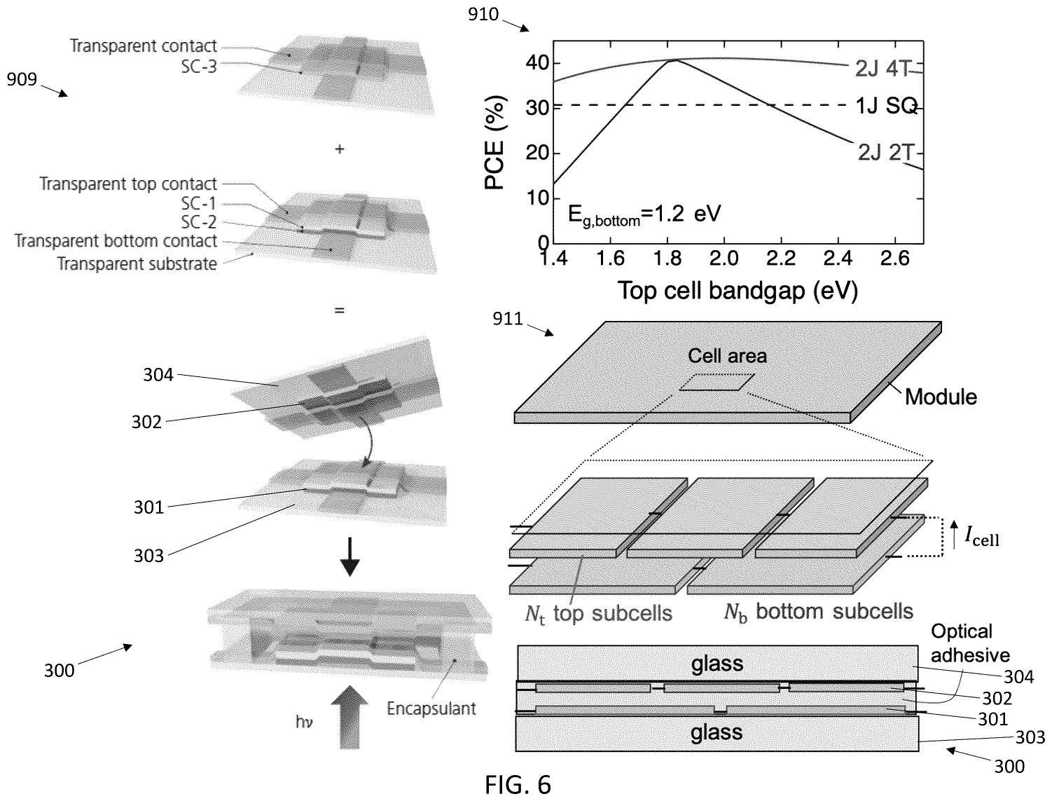

Both 2T and 4T configurations can take advantage of combinations of cells fabricated on different substrates and then bonded together, post-growth, as shown in FIG. 6. For example, one subcell, SC-3, absorbing in the visible is grown on one substrate, and then combined with a tandem with two near-IR absorbing subcells, SC-1 and SC-2 grown on a separate substrate. The low energy absorbing tandem then has a voltage approximately equal to SC-3. The two substrates are then assembled using cold thermocompression bonding or similar, and the four contacts are led to the edges of the two substrates to form the completed cell. (see C. Kim and S. R. Forrest, Adv. Mat. 15, 541 (2003)) Mechanical stacking is also a potential game changer for tandem module design because it enables any combination of top and bottom cells to be current or voltage matched. For example, the best available narrow-gap cell with, for example, a 50% higher current density than the best available wide-gap cell could be series-connected on the bottom substrate using sub-cell areas equal to 2/3 the area of the wide gap cells on the top substrate (FIG. 6), thereby enabling a current-matched 2T module output with the bandgap flexibility of a 4T cell that could substantially improve the efficiency for non-ideal bandgap combinations. This is, in essence, two spectrally-complimentary OPV modules, bonded together and designed to match their output currents and/or voltages to enable 2T operation from imperfect (i.e. practical) material combinations. In one example the best subcell material combinations and relative sizes are identified, optimizing their interconnect patterns (parallel vs. series) and overlay registration to maximize overall GFF. Further antireflection coatings (optical outcoupling layers) needed to maximize transmission of light to the bottom cell while minimizing absorption in the internal transparent contacts were developed. (see Y. Li, X. Guo, Z. Peng, B. Qu, H. Yan, H. Ade, M. Zhang and S. R. Forrest, Proc. of the National Academy of Sciences 117 (35), 21147-21154 (2020))

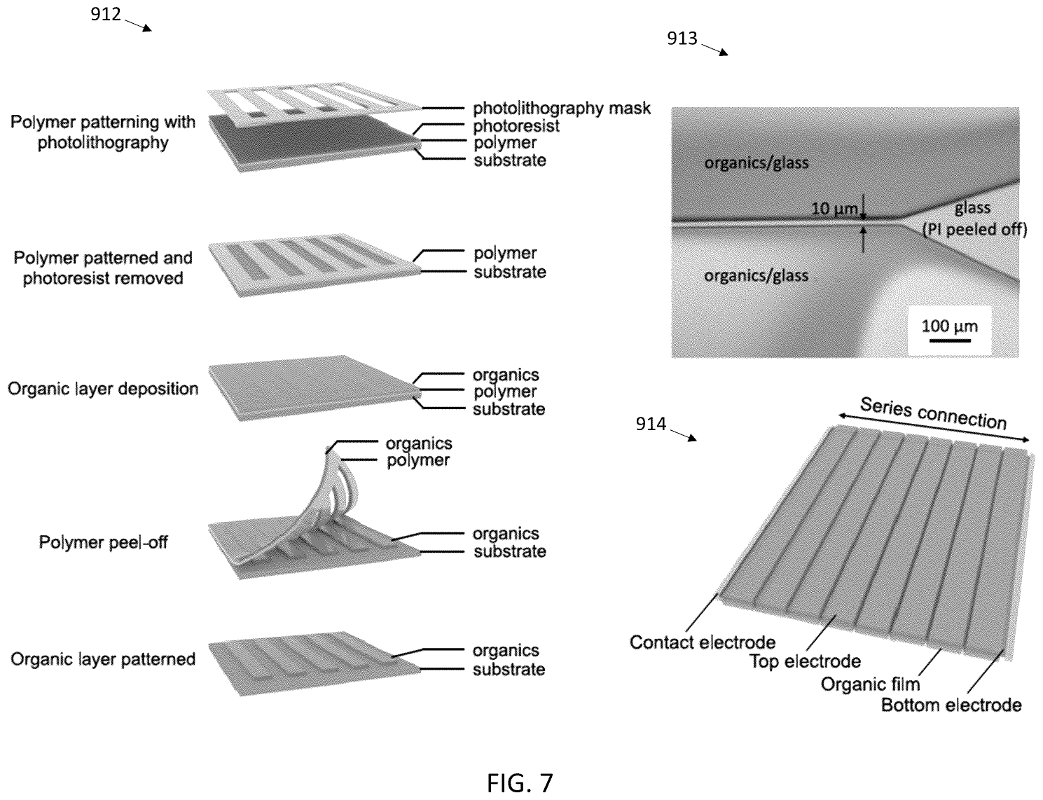

Exemplary multilayer OPVs were fabricated, and performance was characterized from room temperature to 150° C. Once fabricated on ultrathin (50-100 μm) glass or flexible plastic barrier-coated substrates, the devices were encapsulated by sealing with a lid using epoxy and PIB around the package periphery. Standardized tests included measuring V_{OC}, J_{SC}, FF, series and parallel (shunt) resistances, and PCE using a simulated AM1.5G spectrum at 1 sun intensity. To provide the appropriate series and parallel connections needed above on the 50-100 cm² modules used for reliability testing both in the lab and outdoors, a proprietary peel-off process in FIG. 7 was used, which is further described in U.S. patent application Ser. No. 17/684,168, filed Mar. 1, 2022, which is incorporated herein by reference in its entirety. (see X. Huang, D. Fan, Y. Li and S. R. Forrest, Joule 6 (7), 1581-1589 (2022)) This process can achieve geometric fill factors (GFF) greater than 98%, and allows for connection of the anode of one striped cell to the cathode of the adjacent cell, thus forming a series connection between stripes. It is non-destructive to the organic cells since photolithographic patterning is only used to form the polymer peel-off layers on the substrate prior to deposition of the organic thin film OPVs. In some embodiments, the peel-off patterning is essential for achieving the efficient series-parallel double substrate architecture in FIG. 4, that relies on a high GFF.

In some examples the cells are remarkably stable up to 100° C., above which they undergo catastrophic failure due to differential expansion of the device layers. Thus, accelerated aging requires exposing devices to very high intensity (up to 40 suns) illumination; available testing facilities can simultaneously test up to 8 using ultrahigh intensity LED stadium lights, whereas UV exposure is separately applied using UV LEDs. Early work has shown that protype cells have an extrapolated lifetime of T80=30 years in the lab. Further tests have been done to test the reliability of the mini-modules outdoors. Robust package sealing using PIB that does not fail under high humidity and freezing temperatures has been reported in past work. (see H. K. S. Jr., Y. Li and S. R. Forrest, in IEEE PVSC 52 (Seattle, 2024)) The results thus far indicate that bimolecular exciton annihilation is the root cause of degradation. (see K. Ding, X. Huang, Y. Li and S. R. Forrest, Energy & Environmental Science 14 (3), 1584 (2021)) This was investigated by microscopic and electronic analysis of degradation modes vs. incident light intensity, as high intensities should increase the rate of annihilation events.

According to another aspect, the present disclosure relates to a compound of Formula (I) or Formula (II):

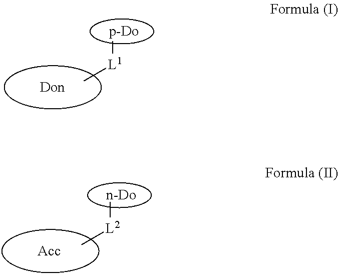

wherein: Don represents a compound capable of functioning as a donor in an organic photovoltaic cell; Acc represents a compound capable of functioning as an acceptor in an organic photovoltaic cell; p-Do represents an organic p-type dopant; n-Do represents an organic n-type dopant; and L¹ and L² independently represent a divalent covalent linking group.

In one embodiment, Don represents a polymeric donor compound.

In one embodiment, L¹ and L² are independently selected from the group consisting of alkylene, cycloalkylene, heteroalkylene, heterocycloalkylene, alkenylene, alkynylene, arylene, heteroarylene, silyl, amine, amide, ester, ether, carbonyl, carbamate, carbonate, sulfamate, sulfonic ester, sulfoximine, sulfonamide, thioether, thioester, disulfide, hydrazine, urea, thiourea, phosphate, phosphonate ester, poly(alkyl ether), heteroatom, and combinations thereof.

In one embodiment, Acc comprises a linear ring system of between three and twenty-five rings D; wherein each ring D is independently a monocyclic ring or a polycyclic fused ring system; wherein each ring D is a 5-membered to 10-membered carbocyclic or heterocyclic ring; each ring D is fused to an adjacent ring D or bonded to an adjacent ring D via a single bond; and each ring D is optionally substituted with one or more substituents R; wherein each occurrence of R independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and any two adjacent substituents R optionally join to form a fused ring.

In one embodiment, Acc comprises six rings D, seven rings D, or eight rings D. In one embodiment, each ring D is independently selected from the group consisting of

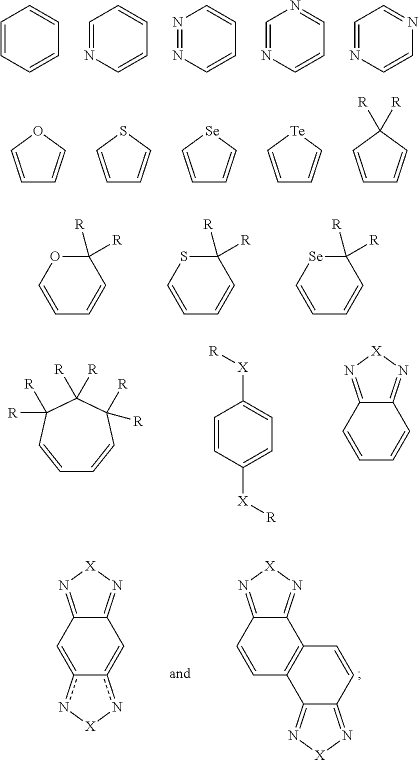

wherein each X is independently selected from the group consisting of oxygen, carbon, hydrogen, sulfur, selenium, and nitrogen; and wherein each ring D is optionally substituted with one or more substituents R.

In one embodiment, Acc comprises one or more groups A; wherein each A is independently selected from the group consisting of:

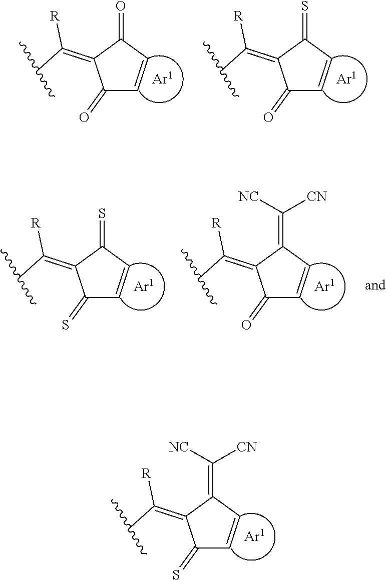

wherein each Ar¹ is independently an aromatic or heteroaromatic ring; each occurrence of R independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and any two adjacent substituents R optionallyjoin to form a fused ring.

In one embodiment, each Ar1 is independently selected from the group consisting of:

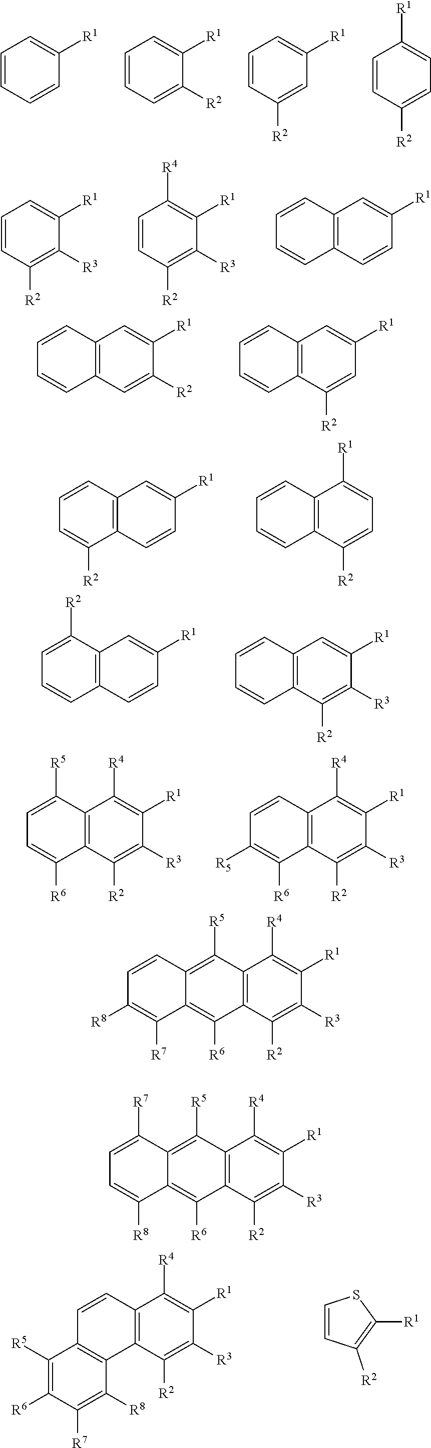

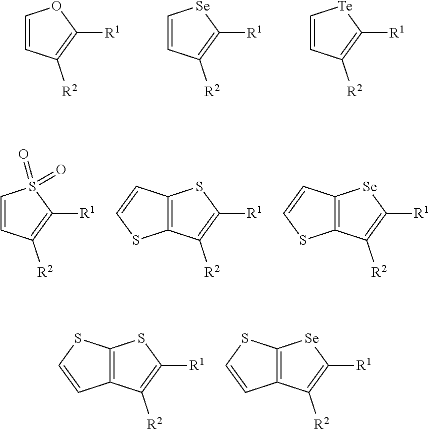

wherein R¹ to R⁸ each independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

In one embodiment, Acc is represented by Formula (A):

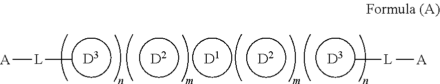

wherein: m is an integer between 0 and 10; n is an integer between 0 and 10; D¹, each D², and each D³ is fused to or covalently bonded to an adjacent ring; D¹, D², and D³ are each independently a monocyclic ring or a polycyclic fused ring system, wherein the monocyclic ring or each ring of the polycyclic fused ring system is a 5-membered to 10-membered carbocyclic or heterocyclic ring; wherein each of D¹, D², and D³ is optionally further substituted with one or more substituents R; L is a divalent linker; each A is independently an acceptor group; each occurrence of R independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents R are optionally joined to form a fused ring.

In one embodiment, D¹ is represented by one of the following structures:

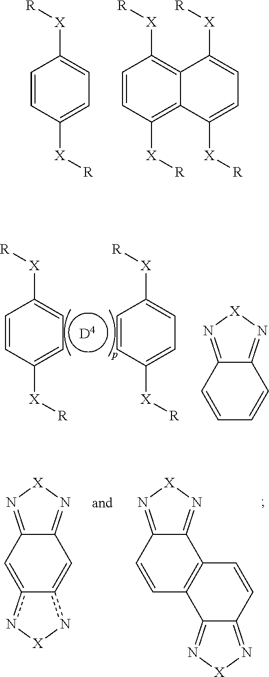

wherein: each X is independently selected from the group consisting of oxygen, carbon, hydrogen, sulfur, selenium, and nitrogen; p is an integer between 0 and 10; wherein D⁴ is a monocyclic ring or a polycyclic fused ring system, wherein the monocyclic ring or each ring of the polycyclic fused ring system is a 5-membered to 10-membered carbocyclic or heterocyclic ring; wherein D⁴ is optionally further substituted with one or more substituents R; and wherein D¹ is optionally substituted with one or more substituents R.

In one embodiment, Acc is represented by Formula (III), Formula (IV), Formula (V), Formula (VI), Formula (VII), or Formula (VIII):

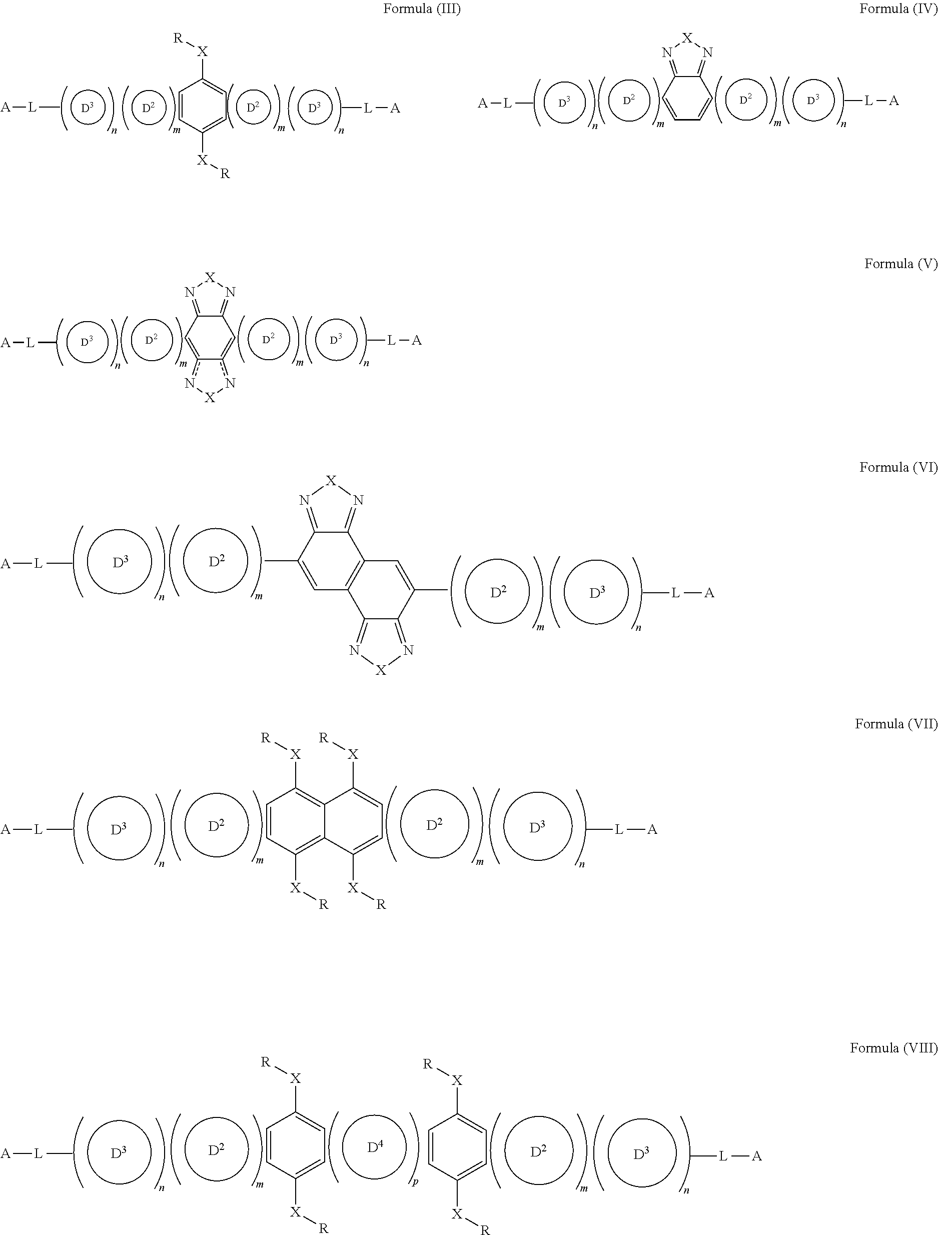

Wherein X is selected from the group consisting of oxygen, carbon, hydrogen, sulfur, selenium, and nitrogen.

In one embodiment, n-Do has one of the following structures:

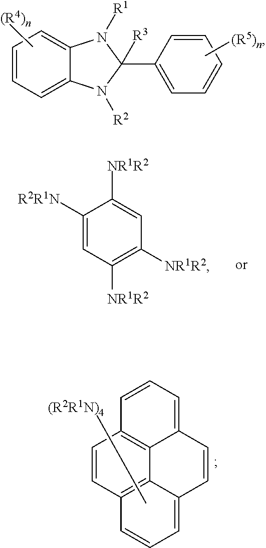

wherein each R¹, R², R³, R⁴, and R⁵ independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents R are optionally joined to form a fused ring; provided that at least one of R¹, R², R³, R⁴, and R⁵ represents the bond to L².

Exemplary n-Do and p-Do structures include, but are not limited to, TTN, BEDT-TTF, BTQBT, pyronin B, acridine orange, rhodamine B, crystal violet,N-DMBI, o-MeO-DMBI-CI or -I, o-MeO-DMBI, DMBI-POH, (2-cyclohexyl-DMBI)₂, (2-ferrocenyl-DMBI)₂, (2-ruthenocenyl-DMBI)₂, (N-DMBI)₂, (2-Cyc-DMBI-Me)₂, TEG-DMBI, N-DPBI, DRBI, p-Me-DMBI, DMBI-Me₂, p-Me-DMBI-Me₂, N-DMBI-Me₂, W(hpp)₄, Mo(tdf)₃, Mo(tfd-COCF₃)₃, Mo(tdf-CO₂Me)₃, Ru(terpy)₂, Ru(^{t}Bu-terpy)₂, CoCp₂, CoCp*₂, Rh(C₅HPh₄)₂, (RhCp₂)₂, (RhCp*Cp)₂, (RuCp*Mes)₂, (RuCp*TEB)2, (FeCp*(PhH))2, BF3, B(Im)4, Zn(C6F5)2, BCF, lithium benzoate, TBAF, TBACI, TBABr, TBABI, TBAOH, TBAAcO, CN6-Cp, CN6-TP.-/TBA+, TMCN3-CP, PEI, TDAE, DMBI-BDZC, DBU, DBN, TBD, DMImC, DQ, BV, Mes2B-TPFB, Tr-TPFB, DDB-F72, TAM, DPDHP, magic blue, EBSA, F4-TCNQ, TCNQ, and BCF, provided that at least one substituent on the compound is replaced with a connection to L1 or L2.

Exemplary n-Do and p-Do structures include, but are not limited to: F4-TCNQ: 2,3,5,6-tetra-fluoro-7,7,8,8-tetracyanoquinodimethane, Magic Blue: tris(4-bromophenyl)ammoniumyl hexachloroantimonate, EBSA: 4-ethylbenzenesulfonic acid, TAM: Triaminomethane, N-DMBI: (4-(1,3-dimethyl-2,3-dihydro-1H-benzoimidazol-2-yl)phenyl)dimethyl-amine, BF3: boron trifluoride, F6-TCNNQ: hexafluorotetracyanonaphthoquinodimethane, CN6-CP: hexacyano-trimethylene-cyclopropane, TBAF: tetrabutylammonium fluoride, BCF: tris(pentafluorophenyl)borane, ZnCF: bis(pentafluorophenyl)zinc, TTN: tetrathianaphthacene, BEDT-TTF: Bis(ethylenedithio)tetrathiafulvalene, BTQBT: bis(1,2,5-thiadiazolo)-p-quinobis(1,3-dithiole), (RuCp*mes)2: pentamethylcyclopentadienyl mesitylene ruthenium dimer, Mo(tfd)3: Molybdenum tris-[1,2-bis(trifluoromethyl)ethane-1,2-dithiolene], Mo(tfd-CO2Me)3: Molybdenum tris(1-(methoxycarbonyl)-2-(trifluoromethyl)ethane-1,2-, dithiolene), Mo(tfd-COCF3)3: Molybdenum tris[1-(trifluoroethanoyl)-2-(trifluoromethyl) ethane-1,2-, dithiolene], Cr2(hpp)4: tetrakis(1,3,4,6,7,8-hexahydro-2H-pyrimido[1,2-a]pyrimidinato)dichromium (II), W2(hpp)4: tetrakis(1,3,4,6,7,8-hexahydro-2H-pyrimido[1,2-a]pyrimidinato)ditungsten (II), Ru(terpy)2: bis(2,2′:6′,2″-terpyridine)ruthenium, Ru(t-but-terpy)2: bis(4,4′,4″-tri-tert-butyl-2,2′: 6′,2″-terpyridine)ruthenium, CoCp2: bis(cyclopentadienyl)cobalt(II), Rh(C5HPh4)2: bis(tetraphenylcyclopentadienyl)rhodium(II), BF3: Boron trifluoride, AIMe3: Trimethylaluminium, BBr3: Boron tribromide, TBAOH: tetrabutyl ammonium hydroxide, TMCN3-CP: trimethyl 2,2′,2″-(cyclopropane-1,2,3-triylidene)-tris(cyanoacetate), PEI: polyethylenimine, BBL: poly(benzoimidazobenzophenanthroline), TDAE: tetrakis(dimethylamino)ethylene, -199-, DMBI-BDZC: (12a,18a)-5,6,12,12a,13,18,18a,19-octahydro-5,6-dimethyl-13,18[1′,2′]-, benzenobisbenzimidazo[1,2-b:2′,1′-d]benzo[i][2.5]benzodiazocine, DBU: amidines 1,8-diazabicyclo[5.4.0]undec-7-ene, DBN: diazabicyclo(5.3.0)non-5-ene, TBD: 1,5,7-triazabicyclo[4.4.0]dec-5-ene, DQ: diquat, BV: benzyl viologen, NHC: N-heterocyclic carbine, DMImC: 1,3-dimethylimidazolium-2-carboxylate, TPFB: tetrakis(pentafluorophenyl)borate, TrTPFB: trityl tetrakis(pentafluorophenyl) borate, DDB: Dodecaborane, PTPADT-SO3Na: poly(4-(3′-sulfonatepropoxy-phenyl)bis(4-phenyl)amine-alt-2,2′-, bithiophen) sodium, CPDT-BT: cyclopenta-[2,1-b;3,4-b′]-dithiophene-alt-4,7-(2,1,3-benzothiadiazole), FPI: fulleropyrrolidinium iodide, BDOPV: benzodifurandione-centered oligo(p-phenylene vinylene), TmPyPB: 3,3′-(5′-(3-(pyridin-3-yl)phenyl)-[1,1′: 3′,1″-terphenyl]-3,3″-diyl)dipyridine, NOSbF6: Nitrosonium hexafluoroantimonate, EBSA: 4-ethylbenzenesulfonic acid, EBSAc: EBSA capped with an o-nitrobenzyl capping moiety, DBSA: dodecylbenzenesulfonic acid, CSA: camphorsulfonic acid, DMDBS: 1,3:2,4-bis(3,4-dimethylbenzylidene)sorbitol, TFP: tetrafluorophthalonitrile, OFN: octafluoronaphthalene, TTF: Tetrathiafulvalene, TMTSF: tetramethyltetraselenafulvalene, DDQ: 2,3-dichloro-5,6-dicyano-1,4-benzoquinone, TMA: 3-(trimethoxysilyl)propan-1-amine, TEDA: N-(3-(triethoxysilyl)propyl)ethane-1,2-diamine), CsF: Cesium fluoride, TBAPF6: tetrabutylammonium hexafluorophosphate, BSA: benzenesulfonic acid, TTF-TCNQ: tetrathiafulvalene-tetracyanoquinodimethane, N-DPBI: 4-(1,3-dimethyl-2,3-dihydro-1H-benzoimidazol-2-yl)-N,N-diphenylaniline, and o-MeO-DMBI: 2-(2-Methoxyphenyl)-1,3-dimethyl-1H-benzoimidazol-3-ium; provided that at least one substituent on the compound is replaced with a connection to L¹ or L².

In one embodiment, p-Do has one of the following structures:

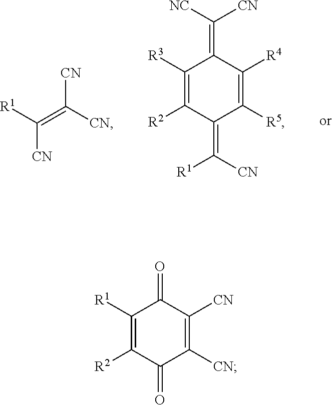

wherein each R¹, R², R³, and R⁴ independently represents hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents R are optionally joined to form a fused ring; provided that at least one of R¹, R², R³, and R⁴, represents the bond to L¹.

In one embodiment, Don has one of the following structures:

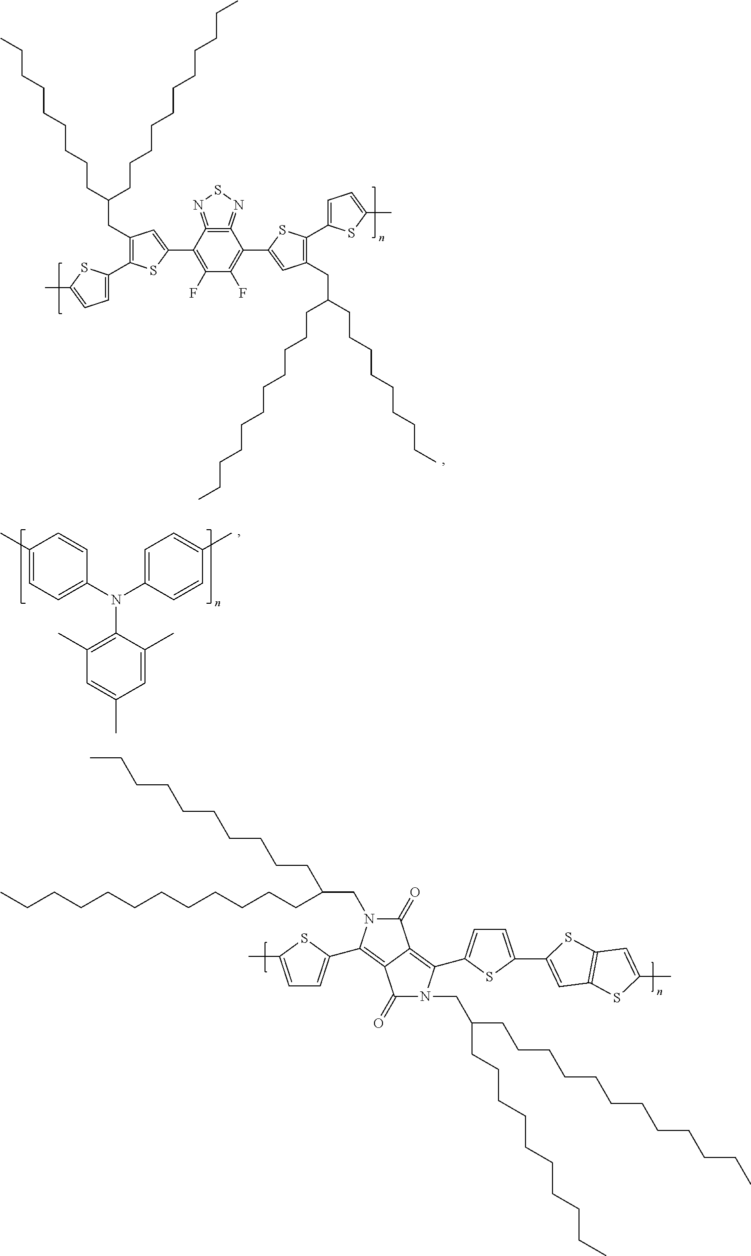

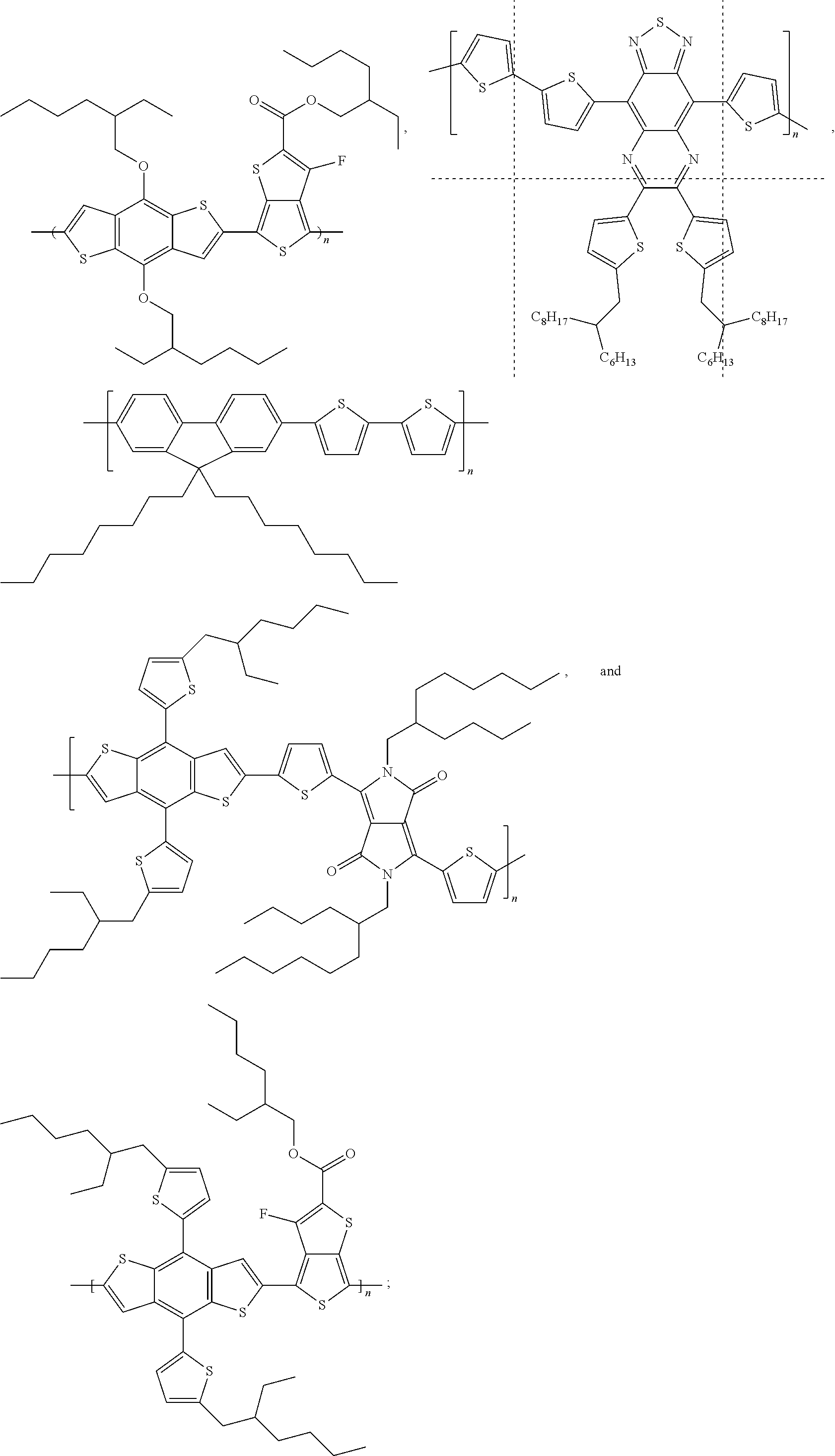

provided that one hydrogen is replaced with the bond to L¹.

Exemplary compounds Acc and Don include, but are in no way limited to, BBL, BO, BTP, BTP-eC9, PM6, CIBDPPV, DCV-DPPTT, DPP-BTz, DPPTTT, F8Py, FBDPPV, IT-4F, IT-M, MEH-PPV, P3EHT, P30T, PBDB-TF, p-DTS(FBTTh₂)₂, PEDOT, polyDOT₃, PQTS12, PSS, PTAA, PTCDI-e, PTEG-1, and Y6, provided that at least one substituent on the compound is replaced with a connection to L¹ or L².

According to another aspect, a formulation comprising a compound described herein is also disclosed.

In one aspect, the disclosure relates to an OPV device comprising a compound of Formula (I) or Formula (II). In one embodiment, the OPV comprises a compound of Formula (I) and a compound of Formula (II). In one embodiment, the OPV device includes an anode; a cathode; and an active material positioned between the anode and cathode, wherein the active material comprises an acceptor and a donor. In one embodiment, the OPV device is an organic photodetector. In one embodiment, the OPV device is a solar cell.

In one embodiment, the OPV device comprises a single-junction organic photovoltaic device. In one embodiment, the OPV device comprises a bulk heterojunction organic photovoltaic device. In one embodiment, the OPV device comprises two electrodes having an anode and a cathode in superposed relation, at least one donor composition, and at least one acceptor composition, wherein the donor-acceptor material or active layer is positioned between the two electrodes. In one embodiment, one or more intermediate layers may be positioned between the anode and the active layer. Additionally, or alternatively, one or more intermediate layers may be positioned between the active layer and cathode.

In one embodiment, the anode comprises a conducting oxide, thin metal layer, or conducting polymer. In one embodiment, the anode comprises a conductive metal oxide. Exemplary conductive metal oxides include, but are not limited to, indium tin oxide (ITO), tin oxide (TO), gallium indium tin oxide (GITO), zinc oxide (ZO), and zinc indium tin oxide (ZITO). In one embodiment, the anode comprises a metal layer. Exemplary metals for the metal layer include, but are not limited to, Ag, Au, Pd, Pt, Ti, V, Zn, Sn, Al, Co, Ni, Cu, Cr, and combinations thereof. In one embodiment, the metal layer comprises a thin metal layer. In one embodiment, the anode 102 comprises a conductive polymer. Exemplary conductive polymers include, but are not limited to, polyanaline (PANI), or 3,4-polyethyl-enedioxythiophene:polystyrenesulfonate (PEDOT:PSS). In one embodiment, thickness of the anode is between about 0.1-100 nm. In one embodiment, thickness of the anode is between about 1-10 nm. In one embodiment, the thickness of the anode is between about 0.1-10 nm. In one embodiment, thickness of the anode is between about 10-100 nm. In one embodiment, the anode comprises a transparent or semi-transparent conductive material.

In one embodiment, the cathode comprises a conducting oxide, a metal layer, or conducting polymer. Exemplary conducting oxide, metal layers, and conducting polymers are described elsewhere herein. In one embodiment, the cathode comprises a thin metal layer. In one embodiment, the cathode comprises a metal or metal alloy. In one embodiment, the cathode may comprise Ca, Al, Mg, Ti, W, Ag, Au, or another appropriate metal, or an alloy thereof. In one embodiment, the thickness of the cathode is between about 0.1-100 nm. In one embodiment, the thickness of the cathode is between about 1-10 nm. In one embodiment, the thickness of the cathode is between about 0.1-10 nm. In one embodiment, the thickness of the cathode is between about 10-100 nm. In one embodiment, cathode comprises a transparent or semi-transparent conductive material.

In one embodiment, the OPV device may comprise one or more charge collecting/transporting intermediate layers positioned between an electrode and the active region or layer. In one embodiment, the OPV device comprises one or more intermediate layers. In one embodiment, the intermediate layer comprises a metal oxide. Exemplary metal oxides include, but are not limited to, MoO₃, MoOX, V₂O₅, ZnO, and TiO₂. In one embodiment, the first intermediate layer has the same composition as the second intermediate layer. In one embodiment, the first intermediate layer and the second intermediate layer have different compositions. In one embodiment, the thickness of the intermediate layers are each independently between about 0.1-100 nm. In one embodiment, the thickness of the intermediate layers are each independently between about 1-10 nm. In one embodiment, the thickness of the intermediate layers are each independently between about 0.1-10 nm. In one embodiment, the thickness of the intermediate layers are each independently between about 10-100 nm.

In one embodiment, the OPV device comprises various layers of a tandem or multi-junction photovoltaic device. In one embodiment, the OPV device comprises two electrodes having an anode and a 204 in superposed relation, at least one donor composition, and at least one acceptor composition positioned within a plurality of active layers or regions between the two electrodes. Additional active layers or regions are also possible. In one embodiment, the anode and the cathode each independently comprise a conducting oxide, thin metal layer, or conducting polymer. Exemplary conducting oxides, metal layers, and conducting polymers are described elsewhere herein.

In one embodiment, the OPV device comprises one or more intermediate layers positioned between the anode and a first active layer. Additionally, or alternatively, at least one intermediate layer may be positioned between the second active layer and cathode. In one embodiment, the OPV device comprises one or more intermediate layers positioned between the first active layer and the second active layer. In one embodiment, the OPV device comprises a first intermediate layer. In one embodiment, the OPV device comprises a second intermediate layer. In one embodiment, the OPV device comprises a third intermediate layer. In one embodiment, the OPV device comprises both first and second intermediate layers. In one embodiment, the OPV device comprises both first and third intermediate layers. In one embodiment, the OPV device comprises both second and third intermediate layers. In one embodiment, the OPV device comprises first, second, and third intermediate layers. In one embodiment, the first, second, and/or third intermediate layer comprises a metal oxide. Exemplary metal oxides are described elsewhere herein.

### Experimental Examples

The best single junction organic photovoltaic (OPV) cells to date have achieved efficiencies exceeding 20% (Z. Zheng, et al., Joule 6 (1), 171-184 (2022)). While OPVs have unique promise for use in semi-transparent power-generating windows, their efficiencies still lag that of other thin film technologies (e.g. CdTe and perovskites), although the efficiency gap has been steadily narrowing. In contrast to perovskites, OPVs have shown extraordinary stabilities of several decades or more (Q. Burlingame, et al., Nature 573, 394 (2019); Y. Li, et al., Nature Comm. 12 (1), 1-9 (2021)). Since OPVs generally use environmentally friendly, low cost, recyclable materials, have very low embodied energy and can easily be combined with other solar technologies in multijunction designs, the possibilities for OPVs as the preferred solar power harvesting technology for windows, rooftop and commodity energy provision is hampered only by their relatively low power conversion efficiencies. It is desirable to close the efficiency gap between OPVs and other thin film solar cell technologies by reducing energy losses in the photogeneration process, and by implementing innovative multijunction designs. New materials and device design strategies can be developed for multijunction cells, and it can be ensured they have long laboratory and outdoor operational lifetimes when deployed in 50-100 cm² mini-modules. Specifically, desirable EOP objectives are a power conversion efficiency of PCE>22%, and preferably PCE≥26% under AM1.5 illumination, and projected operational lifetimes >20 years. Success in this program should catapult OPVs into becoming the leading source of reliable, environmentally friendly and high efficiency, low cost, thin film solar cell technology.

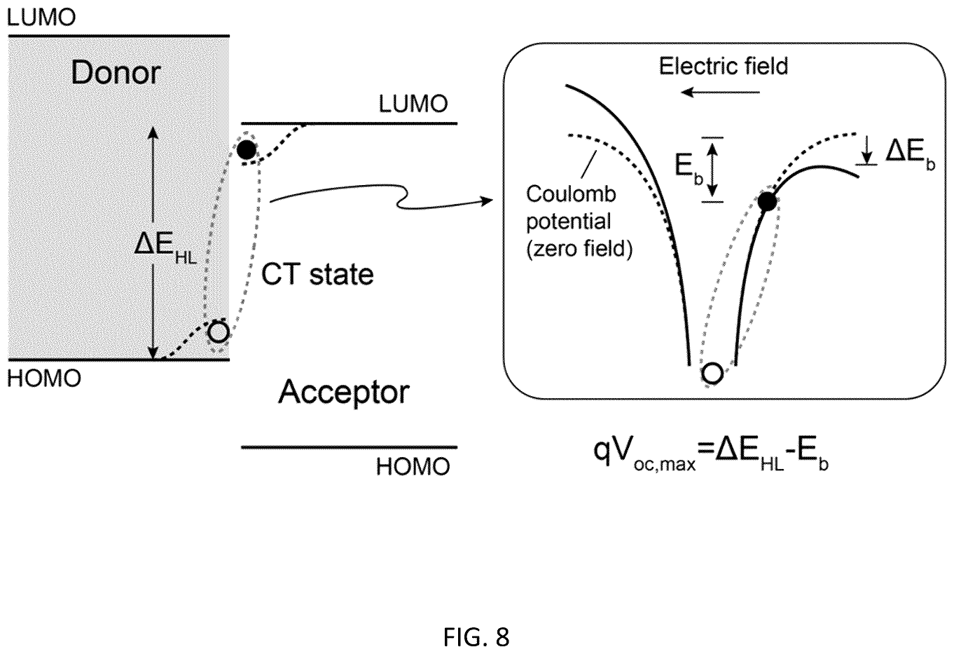

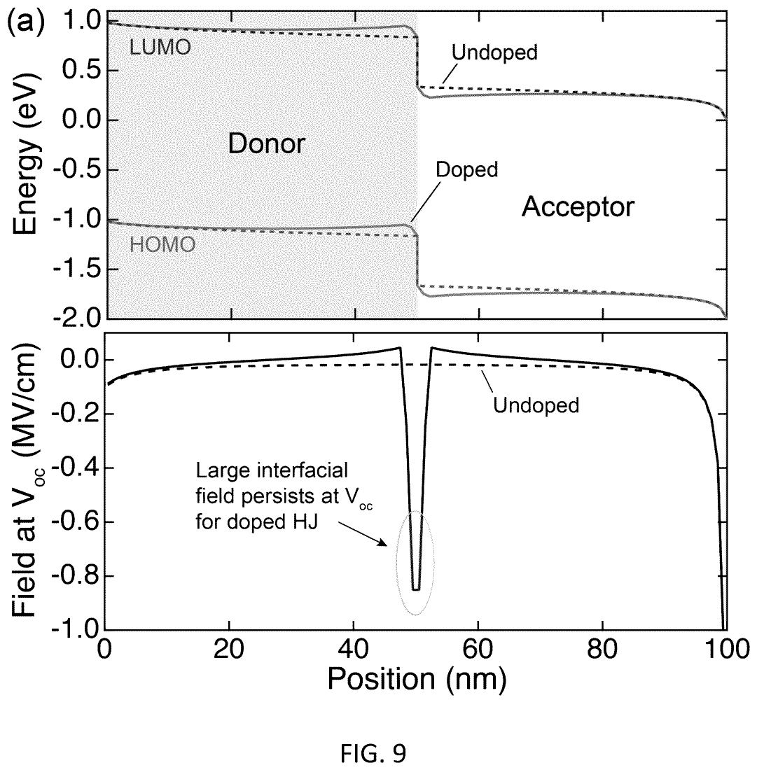

Doping strategy to Decreasing energy losses: Table 1 compares typical performance characteristics of several solar cell technologies. OPVs are distinguished by high open circuit voltage loss relative to their optical gap compared to the other examples. Part of this loss stems from the low radiative efficiency of OPV donor-acceptor (DA) blends, but another component originates from the binding energy of the charge transfer (CT) state at the DA heterojunction (HJ, cf. FIG. 8), which is the key intermediate for photocurrent generation in OPV cells. Forrest and Giebink, and others have shown that the limiting V_{OC} for an OPV is equal to the HJ offset energy minus the CT state binding energy (i.e. the CT state energy), V_{OC,max}=ΔE_{HL}−E_{b}. It is desirable to electrostatically reduce the CT state binding energy and thereby increase V_{OC} by doping the HJ with donors on the A side of the junction and acceptors on the D side. This results in a large built-in electric field at the HJ interface that decreases E_{b} (FIG. 8, inset), thus providing a general approach to increase V_{OC} for any DA material system. The magnitude of the V_{OC} improvement is estimated from drift-diffusion simulations of an OPV HJ in FIG. 9, where the electric field is normally negligible at V_{OC} (dashed lines) but remains large (˜0.8 MV/cm) when the D and A materials are doped at 10¹⁸ cm⁻³ near the interface. A field of this magnitude reduces the CT state binding energy by 0.1-0.2 eV, which leads to an equivalent increase in V_{OC} assuming all other factors remain unchanged. A field of this magnitude reduces the CT state binding energy by 0.1-0.2 eV, which leads to an equivalent increase in Voc assuming all other factors remain unchanged. Let's add in numbers so V_{OC}>0.95V, >1.0V and >1.1V under AM1.5 illumination. The potential for doping-induced V_{oc} improvement is unique to OPVs where free charge generation derives from the strongly bound CT state precursor.

TABLE 1
Comparison of OPV materials

| | E_{g} | V_{oc} | J_{sc} | FF | PCE | E_{g} − qV_{oc} |
|---|---|---|---|---|---|---|
| Material | (eV) | (V) | (mA/cm²) | (%) | (%) | (V) |
| c-Si | 1.10 | 0.74 | 42.6 | 84.9 | 26.7 | 0.36 |
| GaAs | 1.43 | 1.12 | 29.8 | 86.7 | 29.1 | 0.31 |
| CIGS | 1.09 | 0.73 | 39.4 | 80.4 | 23.4 | 0.35 |
| Perovskite | 1.53 | 1.19 | 26.4 | 81.7 | 25.6 | 0.34 |
| Organic | 1.45 | 0.89 | 26.7 | 80.8 | 19.2 | 0.56 |

While doping is straightforward to implement and has demonstrated low voltage loss in vacuum-deposited bilayer OPV cells (P. Kaienburg, et al., ACS Appl. Materials & Inter. 15 (26), 31684 (2023)), it is challenging to realize in state-of-the-art solution-processed bulk heterojunctions (BHJ) because the p- and n-type dopants must be confined within their respective D and A host materials without interdiffusion. In organic semiconductors, a dopant is a molecule whose frontier orbitals (i.e. the valence-like highest occupied molecular orbital, HOMO, or conduction-like lowest unoccupied MO, LUMO) are only slightly offset from the opposite energy level in the “host” organic semiconductor. For example, a donor dopant has its HOMO nearly resonant with the LUMO of the host, thus transferring an excess electron to the host. It is also important to ensure that the dopants do not quench excitons diffusing to the HJ as is observed in organic light-emitting diodes. However, in a BHJ OPV, exciton dissociation occurs very rapidly (˜ps timescale) and thus should outpace the rate of exciton quenching with free and bound (i.e. the dopant counterion) charges. Indeed, conductivity dopants have recently been reported to decrease OPV resistance in a 19.5% cell without any evident exciton quenching (M. Xie, et al., Advanced Energy Materials, 2400214 (2024)).

Studies were performed to find a process to identify and develop a set of donor and acceptor dopants that segregate to the D and A regions, and whose energy levels are within 50 meV of the LUMO and HOMO of the D and A hosts. Adding conductivity dopants has recently been reported to decrease OPV resistance in a 19.5% cell without apparent quenching. The challenge is the difficulty in keeping the dopant within the proper phase, i.e. n-type dopant in A and/or p-type dopant in D in the bulk heterojunction (BHJ). This innovative approach will be to covalently tie the conductivity dopant to the D or A host molecules to ensure complete segregation of the dopant into the proper phase and to control the doping level and uniformity in each phase.

The study started with previously reported p-type and n-type dopants (see A. D. Scaccabarozzi, et al., Chemical Reviews 122 (4), 4420-4492 (2021); S. R. M. Stephen Barlow, et al., in Conjugated Polymers, edited by B. C. T. John R. Reynolds, Terje A. Skotheim (CRC Press, Boca Ratan, 2019), pp. 21-43) in the A and D materials, respectively, and match them with the best reported OPV materials (see J. Bertrandie, et al., Adv. Mater. 34 (35), e2202575 (2022)). Table 2 provides example dopants and their orbital energies, respectively. The n-type dopants have HOMO levels close to the LUMOs of OPV acceptors and are insensitive to oxygen exposure.

TABLE 2
Energies of molecular dopants and representative
OPV D and A materials.

| | HOMO (eV) | LUMO (eV) |
|---|---|---|
| p-type dopant | | |
| TCNE | — | −4.6 |
| DDQ | — | −4.9 |
| F₄TCNQ | — | −5.0 |
| OPV Donor | | |
| PM6 | −5.1 | −3.05 |
| PCE10 | −5.05 | −3.4 |
| P3HT | −4.6 | −2.17 |
| n-type dopant | | |
| BNAH | −5.2 | — |
| BIH | −4.71 | — |
| (Me₂N)₄C₆H₂ | −4.0 | — |
| (Me₂N)₄pyrene | −4.2 | — |
| OPV Acceptor | | |
| Y6 | −5.6 | −4.07 |
| ITIC-4F | −5.9 | −4.1 |
| COi8DFIC | −5.6 | −3.87 |

The dopants are employed in planar heterojunctions. This process allows for straightforward optimization of the dopant and its concentration in a structure where segregation of the dopant in the proper phase is assured. The doped donor layer will be solution-deposited onto an ITO anode, and an acceptor layer added by vacuum deposition. This prevents diffusion of the p-type dopant into the acceptor phase during fabrication. This structure allows for studying the effects of a given p-type dopant on J_{SC}, V_{OC} and FF, in direct comparison to an undoped OPV. For example, the donor polymer, PM6, doped p-type with F₄TCNQ can be combined with a vacuum deposited triazine layer (LUMO energy=−3.74 eV) (see J. Guo, et al., Journal of Materials Chemistry C 9 (3), 939-946 (2021)), followed by an Al cathode. Band bending in such structures can be directly measured by photoelectron spectroscopy. Doped acceptor based OPVs will be studied by a similar process, using an inverted structure. A doped acceptor layer, e.g. Y6 doped with (Me₂N)₂C₆H₄, will be deposited, followed by donor and Al layers by vacuum deposition. The donor for this Y6 based device is TPD (N,N′-Bis(3-methylphenyl)-N,N′-diphenylbenzidine), a common hole transporter in OLEDs with a HOMO energy of 5.1 eV. A similar approach is employed with a range of donor/dopant and acceptor/dopant materials in planar structures to optimize the dopant and concentration for each OPV material.

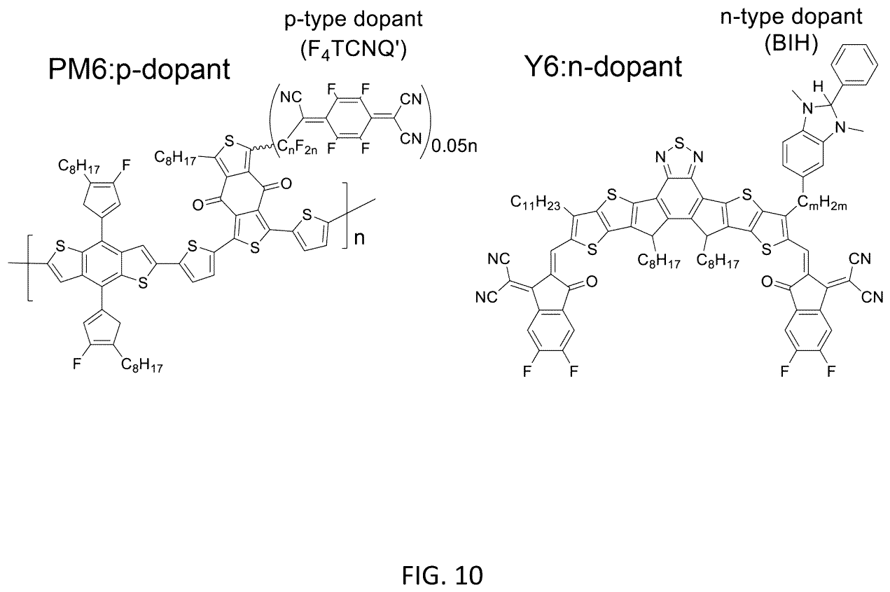

With the best dopant identified for each D and A material, the dopant is attached to the D or A materials with an aliphatic chain (e.g. FIG. 10). These dopant-tied materials are referred to as p-D and n-A. Physically tying the dopant to the D/A material prevents the p-type dopant from diffusing into the A phase or the n-type dopant into the D phase during fabrication of the blended BHJ structure, as previously observed (see M. Xie, et al., Advanced Energy Materials 14 (24) (2024); Y. Tang, et al., ACS Appl Mater Interfaces 12 (11), 13021-13028 (2020); D. Jiang, et al., ACS Energy Letters 7 (5), 1764-1773 (2022)). The BHJ is simply prepared by dissolving the D/p--D and A/n--A materials in a common solvent and casting a thin film. The dopant concentration is readily controlled by adjusting the p-D:D and n-A:A ratios in solution. For molecular D and A materials such as NFAs, the dopant will be incorporated as a side group during synthesis. For polymeric materials, such as PM6, the dopant can be incorporated as a separate monomer during the polymerization, or it can be added post-synthetically. An example of such a post synthetic derivatization would involve a click reaction (see dedicated issue of Chemical Reviews, Vol. 121, 6697-7248 (2021)). An example of such a click reaction involves incorporation of alkyne groups into the periphery of the PM6 polymer by using a PM6 monomer that has the pendent alkynyl groups and couple those moieties with a variant of F4TCNQ that has one of the cyanide groups replaced with an alkyl-azide via a click reaction (L. Liang and D. Astruc, Coord. Chem. Rev. 255 (23-24), 2933-2945 (2011)). Note that the doping level here is controlled by the ratio of the “normal” PM6 monomer to the alkyne substituted one. Modeling suggests that replacing one CN group of F₄TCNQ with a —C₂F₄-(CH₂)ₙ-N₃ group will not markedly alter the LUMO energy. Using a click reaction to tether the dopant to a donor or acceptor is not limited to polymers but can be used on molecular donor or acceptor groups as well. This allows for a modular approach where several dopants can be tested with a given material without requiring a new synthesis to be initiated from the first step.

Achieving the optimal nanophase separation in the BHJ is critical to achieving high efficiency. Phase separation may take place on annealing of the deposited films. Note that the dopant-tied materials will be zwitterionic, i.e. p⁻--D⁺ and n⁺--A⁻. This might lead to phase separation of p⁻--D⁺ and n⁺--A⁻ from D and A material, rather than uniformly distributing p⁻--D⁺ and n⁺--A⁻ throughout the D or A phase. To mitigate this risk, a photo-activated dopant is attached to the D/A materials. Thus, the dopant will not be activated during annealing but will oxidize or reduce the D or A material, respectively, when the doped material is irradiated. For example, a DDQ derivative can dope PM6, which puts the p-type dopant LUMO 200 mV above the filled PM6 HOMO. While the doping reaction is reversible, reforming p-D, the charges can diffuse and be trapped. Sacrificial dopants (i.e. BIH and BNAH) (see Y. Pellegrin and F. Odobel, Comptes Rendus. Chimie 20 (3), 283-295 (2016)) may also be employed in this capacity—chemically changing after oxidation and making back electron transfer impossible.

It is understood that the various embodiments described herein are by way of example only and are not intended to limit the scope of the disclosure. For example, many of the materials and structures described herein may be substituted with other materials and structures without deviating from the spirit of the disclosure. The present compounds as disclosed may therefore include variations from the particular examples and preferred embodiments described herein, as will be apparent to one of skill in the art. It is understood that various theories as to why the embodiments work are not intended to be limiting.

### REFERENCES

The following publications are each hereby incorporated herein by reference in their entirety:
Z. Zheng, J. Wang, P. Bi, J. Ren, Y. Wang, Y. Yang, X. Liu, S. Zhang and J. Hou, Joule 6 (1), 171-184 (2022).
S. R. Forrest, Organic Electronics: Foundations to Applications. (Oxford University Press, Oxford, UK, 2020).
Q. Burlingame, X. Huang, X. Liu, C. Jeong, C. Coburn and S. R. Forrest, Nature 573, 394 (2019).
Y. Li, X. Huang, K. Ding, H. K. Sheriff, L. Ye, H. Liu, C.-Z. Li, H. Ade and S. R. Forrest, Nature Commun. 12 (1), 1-9 (2021).
M. Hölsel, D. Angmo, R. R. Søndergaard, G. A. dos Reis Benatto, J. E. Carlé, M. Jorgensen and F. C. Krebs, Advanced Science 1 (1), 1400002 (2014).
B. Qu and S. R. Forrest, Appl. Phys. Lett. 113, 053302 (2018).
A. D. Scaccabarozzi, A. Basu, F. Aniés, J. Liu, O. Zapata-Arteaga, R. Warren, Y. Firdaus, M. I. Nugraha, Y. Lin and M. Campoy-Quiles, Chem.Rev. 122-, 4420 (2021).
X. Che, Y. Li, Y. Qu and S. R. Forrest, Nature Energy 3, 422 (2018).
X. Huang, B. Sun, Y. Li, C. Jiang, D. Fan, J. Fan and S. R. Forrest, Applied Physics Letters 116 (15) (2020).
C. Kim and S. R. Forrest, Adv. Mat. 15, 541 (2003).
Y. Li, X. Guo, Z. Peng, B. Qu, H. Yan, H. Ade, M. Zhang and S. R. Forrest, Proc. of the National Academy of Sciences 117 (35), 21147-21154 (2020).
X. Huang, D. Fan, Y. Li and S. R. Forrest, Joule 6 (7), 1581-1589 (2022).
H. K. S. Jr., Y. Li and S. R. Forrest, in IEEE PVSC 52 (Seattle, 2024).
K. Ding, X. Huang, Y. Li and S. R. Forrest, Energy & Environmental Science 14 (3), 1584 (2021).
P. Kaienburg, H. Bristow, A. Jungbluth, I. Habib, I. McCulloch, D. Beljonne and M. Riede, ACS Appl. Materials & Inter. 15 (26), 31684 (2023).
M. Xie, L. Zhu, J. Zhang, T. Wang, Y. Li, W. Zhang, Z. Fu, G. Zhao, X. Hao and Y. Lin, Advanced Energy Materials, 2400214 (2024).
A. D. Scaccabarozzi, A. Basu, F. Aniés, J. Liu, O. Zapata-Arteaga, R. Warren, Y. Firdaus, M. I. Nugraha, Y. Lin and M. Campoy-Quiles, Chemical Reviews 122 (4), 4420-4492 (2021).
S. R. M. Stephen Barlow, Xin Lin, Fengyu Zhang, Antoine Kahn, in Conjugated Polymers, edited by B. C. T. John R. Reynolds, Terje A. Skotheim (CRC Press, Boca Ratan, 2019), pp. 21-43.
J. Bertrandie, J. Han, C. S. P. De Castro, E. Yengel, J. Gorenflot, T. Anthopoulos, F. Laquai, A. Sharma and D. Baran, Adv. Mater. 34 (35), e2202575 (2022).
J. Guo, C.-J. Zheng, K. Ke, M. Zhang, H.-Y. Yang, J.-W. Zhao, Z.-Y. He, H. Lin, S.-L. Tao and X.-H. Zhang, Journal of Materials Chemistry C 9 (3), 939-946 (2021).
M. Xie, L. Zhu, J. Zhang, T. Wang, Y. Li, W. Zhang, Z. Fu, G. Zhao, X. Hao, Y. Lin, H. Zhou, Z. Wei and K. Lu, Advanced Energy Materials 14 (24) (2024).
Y. Tang, B. Lin, H. Zhao, T. Li, W. Ma and H. Yan, ACS Appl Mater Interfaces 12 (11), 13021-13028 (2020).
D. Jiang, D. Wang, M. Chen, G. Zhou, Z.-X. Liu, X. Li, H. Zhu, H. Li, H. Chen and C.-Z. Li, ACS Energy Letters 7 (5), 1764-1773 (2022).
L. Liang and D. Astruc, Coord. Chem. Rev. 255 (23-24), 2933-2945 (2011).
Y. Pellegrin and F. Odobel, Comptes Rendus. Chimie 20 (3), 283-295 (2016).

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. An organic photovoltaic (OPV) device, comprising:
a first arrangement of at least one OPV cell; and
a second arrangement of at least one OPV cell;
wherein the first and second arrangements are connected in parallel or series.

2. The device of claim 1, wherein the first arrangement includes a first substrate, and the second arrangement includes a second substrate different from the first.

3. The device of claim 1, wherein the OPV device is a 4 terminal (4T) device.

4. The device of claim 1, wherein the first arrangement is transparent to light in a range in which the second arrangement absorbs, and the second arrangement is transparent to light in a range which the first arrangement absorbs.

5. The device of claim 1, wherein the device has an efficiency under AM1.5 illumination selected from the group consisting of: at least 22%, at least 23%, at least 25%, at least 26%, and at least 27%.

6. The device of claim 1, wherein an operating voltage between the first and second arrangements is balanced based on the number of OPV cells in each arrangement.

7. The device of claim 1, wherein a difference between operating voltages of the first and second arrangements is selected from the group consisting of: less than 1 V, less than 0.5 V, less than 0.3 V, less than 0.1V, less than 0.05V and less than 0.01 V.

8. The device of claim 1, wherein, when light is applied to the OPV device, the absolute value of the difference in current between the first one or more OPVs and the second one or more OPVs is selected from the group consisting of: less than 1 amp, less than 0.5 amps, less than 0.3 amps, less than 0.1 amps, less than 0.05 amps, and less than 0.01 amps.

9. The device of claim 1, wherein the first arrangement comprises at least two OPV cells connected in series.

10. The device of claim 1, wherein the first arrangement comprises at least two OPV cells connected in parallel.

11. The device of claim 1, wherein the second arrangement comprises at least two OPV cells connected in series.

12. The device of claim 1, wherein the second arrangement comprises at least two OPV cells connected in parallel.

13. The device of claim 1, wherein the first and second arrangements are stacked.

14. The device of claim 1, wherein the first arrangement is above the second arrangement, and wherein the first arrangement has a transparency selected from the group consisting of: at least 50% transparent, at least 70% transparent, at least 90% transparent, at least 95% transparent, at least 97% transparent and at least 99% transparent.

15. The device of claim 1, wherein the first arrangement has a first area and the second arrangement has a second area, wherein the second area is selected from the group consisting of: at least 75% of the first area, at least 85% of the first area, at least 95% of the first area, at least 97% of the first area, and at least 99% of the first area.

16. The device of claim 1, wherein the at least one OPV cell in the first arrangement has a narrow bandgap and the at least one OPV cell in the second arrangement has a wide bandgap.

17. The device of claim 1, wherein light incident upon the OPV device interacts with the first arrangement and then interacts with the second arrangement.

18. The device of claim 1, wherein the first arrangement absorbs light in a first wavelength range and wherein the second arrangement absorbs light in a second wavelength range.

19. The device of claim 1, wherein the device has an open circuit voltage (Voc) selected from the group consisting of: greater than 0.95V, greater than 1.0V, and greater than 1.1V under AM1.5 illumination

20. The device of claim 1, wherein the device comprises a flat panel display, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign.
